(19) United States
(12) Patent Application Publication
(10) Pub. No.: US 2026/0282389 A1
(43) Pub. Date: Sep. 17, 2026

(54) STORAGE DEVICE

(71) Applicant: Kioxia Corporation, Tokyo (JP)

(72) Inventors: Viktoria Diana SCHLYKOW, Kamakura Kanagawa (JP); Reika TANAKA, Yokohama Kanagawa (JP); Masakazu GOTO, Tsukuba Ibaraki (JP); Takeshi IWASAKI, Kuwana Mie (JP)

(21) Appl. No.: 19/327,808

(22) Filed: Sep. 12, 2025

(30) Foreign Application Priority Data
Mar. 14, 2025 (JP) 2025-041535

(51) Int. Cl. H10B 61/00; G01R 33/09; H10B 63/00; H10N 50/10; H10N 50/85; H10N 70/00

(52) U.S. Cl. CPC H10B 61/10; G01R 33/098; H10B 63/20; H10N 50/10; H10N 50/85; H10N 70/883

(57) ABSTRACT

A storage device includes a memory cell that includes: a first conductive layer; a switching layer; a third conductive layer; a resistive layer; and a second conductive layer in this order. The switching layer includes: a first oxide of a first element selected from among Al, Si, Ge, Zr, Y, Ta, La, Ce, Ti, Hf, and Mg; a second element selected from among Al, Zn, Sn, Ga, In, and Bi; and a third element selected from among Te, S, Se, and Sb. The switching layer includes first, second, and third regions. The first region is between the second and third regions. The sum of the atomic concentration of the second element and the atomic concentration of the third element in the second and third regions is greater than the sum of the atomic concentration of the second element and the atomic concentration of the third element in the first region.

### CROSS-REFERENCE TO RELATED APPLICATION(S)

This application is based upon and claims the benefit of priority from Japanese Patent Application No. 2025-041535, filed Mar. 14, 2025, the entire contents of which are incorporated herein by reference.

### FIELD

Embodiments described herein relate generally to a storage device.

### BACKGROUND

Large-capacity non-volatile storage devices include, for example, a cross-point two-terminal storage device. The cross-point two-terminal storage devices facilitate finer and more highly integrated memory cell structures.

The memory cells of the cross-point two-terminal storage device includes, for example, a resistive element, and a switching element. Since the memory cell includes the switching element, the current is prevented from flowing through memory cells other than the selected memory cell.

The switching element is required to have excellent characteristics, such as low leakage current, high on-state current, and high reliability.

### BRIEF DESCRIPTION OF THE DRAWINGS

FIG. 1 is a block diagram of a storage device of a first embodiment.

FIG. 2 is a schematic sectional view of a memory cell of the storage device of the first embodiment.

FIG. 3 is a diagram illustrating a problem of the storage device of the first embodiment.

FIG. 4 is a diagram illustrating the current-voltage characteristics of a switching element in the storage device of the first embodiment.

FIG. 5 is a schematic sectional view of a memory cell of a storage device of a comparative example.

FIG. 6 is a schematic sectional view of a memory cell of a storage device according to a first modification of the first embodiment.

FIG. 7 is a schematic sectional view of a memory cell of a storage device according to a second modification of the first embodiment.

FIG. 8 is a schematic sectional view of a memory cell of a storage device according to a third modification of the first embodiment.

FIG. 9 is a schematic sectional view of a memory cell of a storage device according to a fourth modification of the first embodiment.

FIG. 10 is a schematic sectional view of a memory cell of a storage device of a second embodiment.

FIGS. 11-12 are schematic sectional views showing a method of manufacturing the memory cell of the storage device of the second embodiment.

FIG. 13 is a schematic sectional view of a memory cell of a storage device of a third embodiment.

FIGS. 14-17 are schematic sectional views showing a method of manufacturing the memory cell of the storage device of the third embodiment.

FIG. 18 is a schematic sectional view of a memory cell of a storage device of a fourth embodiment.

FIG. 19 is a schematic sectional view of a memory cell of a storage device of a fifth embodiment.

FIG. 20 is a diagram illustrating the current-voltage characteristics of a memory element in the storage device of the fifth embodiment.

FIG. 21 is a diagram illustrating a first operation example of memory operation of the storage device of the fifth embodiment.

FIG. 22 is a diagram illustrating a second operation example of memory operation of the storage device of the fifth embodiment.

FIG. 23 is a diagram illustrating the current-voltage characteristics of a memory element in a storage device according to a first modification of the fifth embodiment.

FIG. 24 is a diagram illustrating a third operation example of memory operation of the storage device according to the first modification of the fifth embodiment.

FIG. 25 is a diagram illustrating a fourth operation example of memory operation of the storage device according to the first modification of the fifth embodiment.

FIG. 26 is a diagram illustrating the current-voltage characteristics of a memory element in a storage device according to a second modification of the fifth embodiment.

FIG. 27 is a diagram illustrating a fifth operation example of memory operation of the storage device according to the second modification of the fifth embodiment.

FIG. 28 is a diagram illustrating a sixth operation example of memory operation of the storage device according to the second modification of the fifth embodiment.

FIG. 29 is a diagram illustrating the current-voltage characteristics of a memory element of a storage device according to a third modification of the fifth embodiment.

FIG. 30 is a diagram illustrating a seventh operation example of memory operation of the storage device according to the third modification of the fifth embodiment.

FIG. 31 is a diagram illustrating an eighth operation example of memory operation of the storage device according to the third modification of the fifth embodiment.

FIG. 32 is a schematic sectional view of a memory cell of a storage device of a sixth embodiment.

### DETAILED DESCRIPTION

Embodiments provide a storage device that includes a switching element having excellent characteristics.

In general, according to one embodiment, a storage device of an embodiment includes: a memory cell including: a first conductive layer; a second conductive layer; a third conductive layer provided between the first conductive layer and the second conductive layer; a switching layer provided between the first conductive layer and the third conductive layer; and a resistive layer provided between the third conductive layer and the second conductive layer, wherein the switching layer includes: a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the at least one first element and is selected from a group consisting of aluminum (Al), zinc (Zn), tin (Sn), gallium (Ga), indium (In), and bismuth (Bi); and at least one third element selected from a group consisting of tellurium (Te), sulfur (S), selenium (Se), and antimony (Sb), the switching layer includes a first region, a second region, and a third region in a cross-section parallel to a first direction connecting the first conductive layer and the second conductive layer, and the first region is provided in the cross-section between the second region and the third region in a second direction perpendicular to the first direction, the first region includes the first oxide; the second region and the third region include the second element and the third element; a second sum of an atomic concentration of the second element and an atomic concentration of the third element in the second region is greater than a first sum of an atomic concentration of the second element and an atomic concentration of the third element in the first region; and a third sum of an atomic concentration of the second element and an atomic concentration of the third element in the third region is greater than the first sum.

Hereinafter, embodiments of the present invention will be described with reference to the drawings. Note that in the following description, the same or similar elements are assigned the same symbols, and description of elements and the like that have been described once will not be described again when appropriate.

For qualitative analysis and quantitative analysis of chemical compositions of elements of a storage device described in the present specification, Rutherford backscattering spectroscopy (RBS), secondary ion mass spectroscopy (SIMS), energy dispersive X-ray spectroscopy (EDX), electron energy loss spectroscopy (EELS) can be used, for example. To measure the thicknesses of elements of the storage device, the distances between the components and the like, a transmission electron microscope (TEM) can be used, for example. To identify the constituent substances of the elements of the storage device, and measure the presence rates of the constituent substances, identify the bonding states of the constituent substances, identify the local structures (atomic distances and coordination numbers) of the constituent substances, measure the chemical states of the constituent substances, and compare the concentrations of the constituent substances, X-ray photoelectron spectroscopy (XPS), X-ray absorption fine structure (XAFS), Raman spectroscopy (Raman), a scanning transmission electron microscope (STEM), or EELS can be used, for example. Electron energy loss spectroscopy (EELS) can be used, for example, to compare the densities of chemical bonds between the constituent substances of the elements of the storage device. Electron beam absorbed current (EBAC) can be used to measure the electrical resistivities of the elements of the storage device.

### First Embodiment

The storage device according to a first embodiment includes a memory cell that includes: a first conductive layer; a second conductive layer; a third conductive layer provided between the first conductive layer and the second conductive layer; a switching layer provided between the first conductive layer and the third conductive layer; and a resistive layer provided between the third conductive layer and the second conductive layer. The switching layer includes: a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the at least one first element and is selected from a group consisting of aluminum (Al), zinc (Zn), tin (Sn), gallium (Ga), indium (In), and bismuth (Bi); and at least one third element selected from a group consisting of tellurium (Te), sulfur (S), selenium (Se), and antimony (Sb). The switching layer includes a first region, a second region, and a third region in a cross-section parallel to a first direction connecting the first conductive layer and the second conductive layer. The first region is provided in the cross-section between the second region and the third region in a second direction perpendicular to the first direction. The first region includes the first oxide, and the second region and the third region include the second element and the third element. A second sum of the atomic concentration of the second element and the atomic concentration of the third element in the second region is greater than a first sum of the atomic concentration of the second element and the atomic concentration of the third element in the first region. A third sum of the atomic concentration of the second element and the atomic concentration of the third element in the third region is greater than the first sum.

The storage device according to the first embodiment further includes a plurality of first lines, and a plurality of second lines that intersect the plurality of first lines. The memory cell is provided in a region where one of the plurality of first lines intersects one of the plurality of second lines.

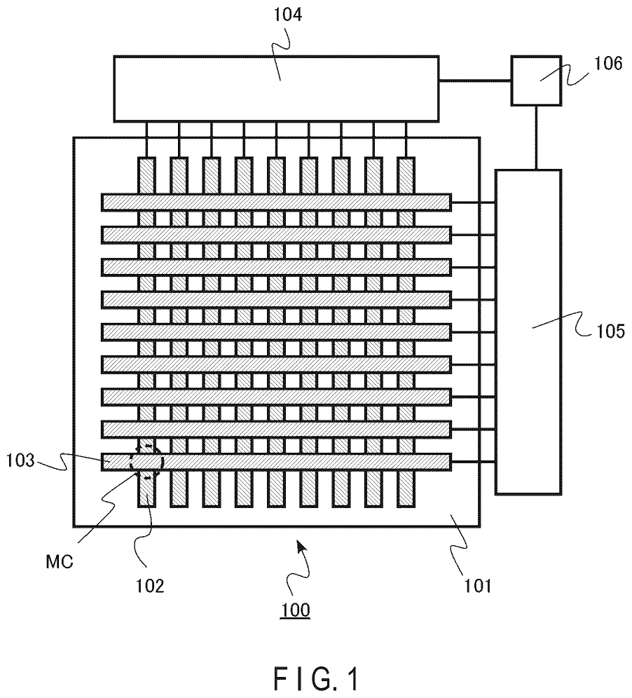

FIG. 1 is a block diagram of the storage device of the first embodiment.

A memory cell array 100 of the storage device of the first embodiment includes, for example, a plurality of word lines 102, and a plurality of bit lines 103 that intersect the word lines 102, via an insulating layer, on a semiconductor substrate 101. The bit lines 103 are provided on an upper layer of the word lines 102. A first control circuit 104, a second control circuit 105, and a sense circuit 106 are provided, as peripheral circuits, around the memory cell array 100.

The word lines 102 are examples of first lines. The bit lines 103 are examples of second lines.

A plurality of memory cells MC are respectively provided in regions where the word lines 102 intersect the bit lines 103. The storage device of the first embodiment is a two-terminal magnetoresistive memory that has a cross-point structure.

Each of the word lines 102 is connected to the first control circuit 104. Each of the bit lines 103 is connected to the second control circuit 105. The sense circuit 106 is connected to the first control circuit 104 and the second control circuit 105.

The first control circuit 104 and the second control circuit 105 have, for example, functions such as of selecting a desired memory cell MC, writing data into the memory cell MC, reading data from the memory cell MC, and erasing data in the memory cell MC. When data is read, the data in the memory cell MC is read according to an amount of current flowing between the word line 102 and the bit line 103, or a change in potential on the bit line 103. The sense circuit 106 has functions of determining the amount of current or change in potential, and determining the polarity of the data. For example, it is determined whether the data is “0” or “1”.

The first control circuit 104, the second control circuit 105, and the sense circuit 106 are made up of, for example, electronic circuits using semiconductor devices formed on the semiconductor substrate 101.

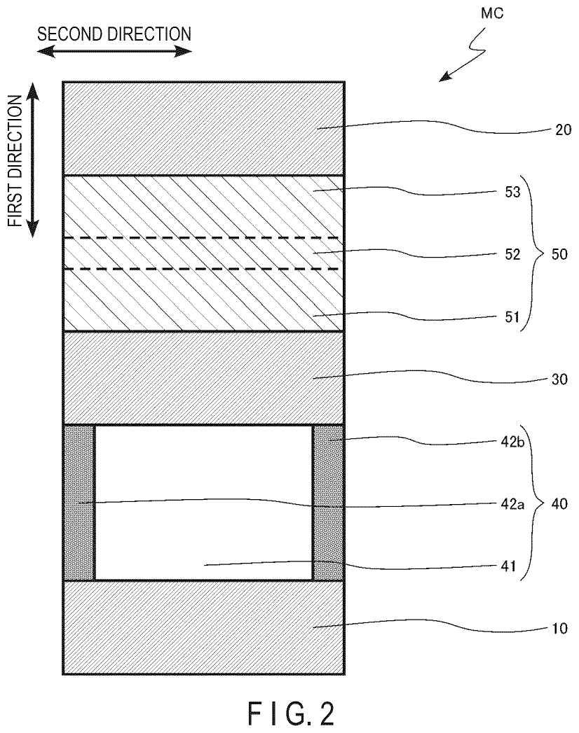

FIG. 2 is a schematic sectional view of the memory cell of the storage device of the first embodiment. FIG. 2 shows a cross-section of one memory cell MC indicated by, for example, a broken-line circle in the memory cell array 100 in FIG. 1. FIG. 2 shows a cross-section in parallel with a first direction that connects the lower electrode 10 and the upper electrode 20.

As shown in FIG. 2, the memory cell MC includes a lower electrode 10, an upper electrode 20, an intermediate electrode 30, a switching layer 40, and a resistive layer 50. The switching layer 40 includes an inner region 41, a first side wall region 42a, and a second side wall region 42b. Hereinafter, the first side wall region 42a and the second side wall region 42b are individually or collectively called a side wall region 42. The resistive layer 50 includes a fixed layer 51, a tunnel layer 52, and a free layer 53.

The lower electrode 10 is an example of a first conductive layer. The upper electrode 20 is an example of a second conductive layer. The intermediate electrode 30 is an example of a third conductive layer. The inner region 41 is an example of the first region. The first side wall region 42a is an example of the second region. The second side wall region 42b is an example of the third region.

The lower electrode 10, the switching layer 40, and the intermediate electrode 30 make up a switching element of the memory cell MC. The intermediate electrode 30, the resistive layer 50, and the upper electrode 20 make up a resistive element of the memory cell MC.

The lower electrode 10 is connected to the word line 102. The lower electrode 10 is made of, for example, metal. The lower electrode 10 contains, for example, at least one substance selected from a group consisting of carbon, carbon nitride, tungsten, tungsten carbide, tungsten nitride, titanium, titanium nitride, tantalum, tantalum carbide, tantalum nitride, molybdenum, tin, and germanium. The lower electrode 10 may be part of the word line 102.

The lower electrode 10 contains, for example, tungsten (W), tin (Sn), molybdenum (Mo), or germanium (Ge).

The upper electrode 20 is connected to the bit line 103. The upper electrode 20 is made of, for example, metal. The upper electrode 20 contains, for example, at least one substance selected from a group consisting of carbon, carbon nitride, tungsten, tungsten carbide, tungsten nitride, titanium, titanium nitride, tantalum, tantalum carbide, tantalum nitride, molybdenum, tin, and germanium. The upper electrode 20 may be part of the bit line 103.

The intermediate electrode 30 is provided between the lower electrode 10 and the upper electrode 20. The intermediate electrode 30 is made of, for example, metal. The intermediate electrode 30 contains, for example, at least one substance selected from a group consisting of carbon, carbon nitride, tungsten, tungsten carbide, tungsten nitride, titanium, titanium nitride, tantalum, tantalum carbide, tantalum nitride, molybdenum, tin, and germanium.

The intermediate electrode 30 contains, for example, tungsten (W), tin (Sn), molybdenum (Mo), or germanium (Ge).

The switching layer 40 is provided between the lower electrode 10 and the intermediate electrode 30. The switching layer 40 is in contact with the lower electrode 10 and the intermediate electrode 30.

The thickness of the switching layer 40 in the first direction from the lower electrode 10 toward the upper electrode 20 ranges between, for example, 5 nm and 50 nm, inclusive. More preferably, the thickness of the switching layer 40 in the first direction ranges between, for example, 5 nm and 20 nm, inclusive. The length of the switching layer 40 in the second direction perpendicular to the first direction ranges between, for example, 10 nm and 50 nm, inclusive.

The switching layer 40 has a function of preventing an increase in the leakage current that flows through a semi-selected cell. The switching layer 40 has nonlinear current-voltage characteristics in which the current steeply rises at a specific threshold voltage.

The switching layer 40 includes the first oxide of the first element, the second element, and the third element.

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg). The first oxide is, for example, aluminum oxide, silicon oxide, germanium oxide, zirconium oxide, yttrium oxide, tantalum oxide, lanthanum oxide, cerium oxide, titanium oxide, hafnium oxide, or magnesium oxide.

The second element is an element different from the first element. The second element is at least one element selected from a group consisting of aluminum(Al), zinc (Zn), tin (Sn), gallium (Ga), indium (In), and bismuth (Bi). The third element is at least one element selected from a group consisting of tellurium (Te), sulfur (S), selenium (Se), and antimony (Sb).

The switching layer 40 includes, for example, a compound of the second element and the third element. The compound of the second element and the third element contains, for example, aluminum telluride, zinc telluride, tin telluride, gallium telluride, indium telluride, bismuth telluride, aluminum sulfide, zinc sulfide, tin sulfide, gallium sulfide, indium sulfide, bismuth sulfide, aluminum selenide, zinc selenide, tin selenide, gallium selenide, indium selenide, bismuth selenide, aluminum antimonide, zinc antimonide, tin antimonide, gallium antimonide, indium antimonide, or bismuth antimonide.

The sum of the atomic concentrations of the first element, the second element, the third element, and oxygen (O) in the switching layer 40 ranges between, for example, 80% and 100%, inclusive.

The ratio of the sum of the atomic concentrations of the first element and oxygen (O) to the sum of the atomic concentrations of the first element, the second element, the third element, and the oxygen (O) in the switching layer 40 ranges between, for example, 5% and 90%, inclusive.

The atomic concentration of the first element contained in the switching layer 40 ranges between, for example, 2% and 30%, inclusive. The atomic concentration of the second element contained in the switching layer 40 ranges between, for example, 5% and 50%, inclusive. The atomic concentration of the third element contained in the switching layer 40 ranges between, for example, 5% and 50%, inclusive. The atomic concentration of oxygen contained in the switching layer 40 ranges between, for example, 4% and 60%, inclusive.

The atomic concentration of the third element contained in the switching layer 40 is, for example, equal to or greater than 0.8 times and equal to or less than 1.2 times the atomic concentration of the second element.

The switching layer 40 contains, for example, at least one fourth element selected from a group consisting of carbon (C), boron (B), phosphorus (P), and nitrogen (N). The atomic concentration of the fourth element contained in the switching layer 40 ranges between, for example, 5% and 20%, inclusive.

The switching layer 40 includes the inner region 41 and the side wall region 42. The side wall region 42 includes the first side wall region 42a, and the second side wall region 42b.

In the second direction that is perpendicular to the first direction in the cross-section parallel to the first direction connecting the lower electrode 10 and the upper electrode 20, the inner region 41 is provided between the first side wall region 42a and the second side wall region 42b. The first side wall region 42a and the second side wall region 42b are provided between the lower electrode 10 and the intermediate electrode 30 in the first direction, for example. The first side wall region 42a and the second side wall region 42b are in contact with the lower electrode 10 and the intermediate electrode 30 in the first direction, for example.

The inner region 41 includes the first oxide. The inner region 41 may or may not include the second element and the third element. The inner region 41 includes, for example, the second element and the third element. The inner region 41 includes, for example, a compound of the second element and the third element.

The side wall region 42 includes the second element and the third element. The first side wall region 42a and the second side wall region 42b include the second element and the third element.

The side wall region 42 includes, for example, a compound of the second element and the third element. The first side wall region 42a and the second side wall region 42b include the compound of the second element and the third element.

The side wall region 42 may or may not include the first oxide. The first side wall region 42a and the second side wall region 42b may or may not include the first oxide.

The side wall region 42 includes, for example, the first oxide. The first side wall region 42a and the second side wall region 42b include, for example, the first oxide.

A second sum of the atomic concentration of the second element and the atomic concentration of the third element in the first side wall region 42a is greater than the first sum of the atomic concentration of the second element and the atomic concentration of the third element in the inner region 41. The difference between the second sum and the first sum ranges between, for example, 1% and 50%, inclusive. The second sum is, for example, equal to or greater than 1.2 times and equal to or less than 5 times the first sum.

A third sum of the atomic concentration of the second element and the atomic concentration of the third element in the second side wall region 42b is greater than the first sum of the atomic concentration of the second element and the atomic concentration of the third element in the inner region 41. The difference between the third sum and the first sum ranges between, for example, 1% and 50%, inclusive. The third sum is, for example, equal to or greater than 1.2 times and equal to or less than 5 times the first sum.

The ratio of the sum of the atomic concentration of the second element and the atomic concentration of the third element to the sum of the atomic concentration of the first element, the atomic concentration of the second element, the atomic concentration of the third element, and the atomic concentration of oxygen in the side wall region 42 is greater than, for example, the ratio of the sum of the atomic concentration of the second element and the atomic concentration of the third element to the sum of the atomic concentration of the first element, the atomic concentration of the second element, the atomic concentration of the third element, and the atomic concentration of oxygen in the inner region 41.

The atomic concentration of the second element in the side wall region 42 is greater than, for example, the atomic concentration of the second element in the inner region 41. The atomic concentration of the third element in the side wall region 42 is greater than, for example, the atomic concentration of the third element in the inner region 41.

The atomic concentration of the second element in the first side wall region 42a is greater than, for example, the atomic concentration of the second element in the inner region 41. The atomic concentration of the third element in the first side wall region 42a is greater than, for example, the atomic concentration of the third element in the inner region 41.

The atomic concentration of the second element in the second side wall region 42b is greater than, for example, the atomic concentration of the second element in the inner region 41. The atomic concentration of the third element in the second side wall region 42b is greater than, for example, the atomic concentration of the third element in the inner region 41.

The concentration of the compound of the second element and the third element in the side wall region 42 is greater than, for example, the concentration of the compound of the second element and the third element in the inner region 41. The concentration of the compound of the second element and the third element in the first side wall region 42a is greater than, for example, the concentration of the compound of the second element and the third element in the inner region 41. The concentration of the compound of the second element and the third element in the second side wall region 42b is greater than, for example, the concentration of the compound of the second element and the third element in the inner region 41. Note that the concentration of the compound of the second element and the third element is given in molarity, for example.

The density of chemical bonds between the second element and the third element in the side wall region 42 is greater than, for example, the density of chemical bonds between the second element and the third element in the inner region 41. The density of chemical bonds between the second element and the third element in the first side wall region 42a is greater than, for example, the density of chemical bonds between the second element and the third element in the inner region 41. The density of chemical bonds between the second element and the third element in the second side wall region 42b is greater than, for example, the density of chemical bonds between the second element and the third element in the inner region 41.

The electrical resistivity in the side wall region 42 is less than, for example, a first electrical resistivity in the inner region 41. A second electrical resistivity in the first side wall region 42a is less than, for example, the first electrical resistivity in the inner region 41. A third electrical resistivity in the second side wall region 42b is less than, for example, the first electrical resistivity in the inner region 41.

The thickness of the side wall region 42 in the second direction ranges between, for example, 1 nm and 5 nm, inclusive. The thickness of the first side wall region 42a in the second direction ranges between, for example, 1 nm and 5 nm, inclusive. The thickness of the second side wall region 42b in the second direction ranges between, for example, 1 nm and 5 nm, inclusive.

The thickness of the side wall region 42 in the second direction is less than, for example, the thickness of the inner region 41 in the second direction. The thickness of the side wall region 42 in the second direction is equal to or less than, for example, one-half the thickness of the inner region 41 in the second direction.

The resistive layer 50 is provided between the intermediate electrode 30 and the upper electrode 20. The resistive layer 50 includes the fixed layer 51, the tunnel layer 52, and the free layer 53. The resistive layer 50 includes a magnetic tunnel junction made up of the fixed layer 51, the tunnel layer 52, and the free layer 53.

The resistive layer 50 has a function of storing data according to a change in resistance thereof. The resistive layer 50 has, for example, characteristics in which its electrical resistance changes with application of a predetermined voltage.

The fixed layer 51 is a ferromagnetic body. In the fixed layer 51, the magnetization direction does not change with a predetermined write voltage applied thereto, and the magnetization direction is fixed in a specific direction.

The tunnel layer 52 is an insulator. In the tunnel layer 52, electrons pass therethrough by the tunneling effect.

The free layer 53 is a ferromagnetic body. In the free layer 53, the magnetization direction changes with the predetermined write voltage applied thereto. The magnetization direction of the free layer 53 can be in any of states that are a state parallel with the magnetization direction of the fixed layer 51 and a state antiparallel with the magnetization direction of the fixed layer 51. For example, by applying a voltage and causing current to flow between the intermediate electrode 30 and the upper electrode 20, the magnetization direction of the free layer 53 can be changed.

By changing the magnetization direction of the free layer 53, the electrical resistance of the resistive layer 50 changes. When the magnetization direction of the free layer 53 is in the state antiparallel with the magnetization direction of the fixed layer 51, a high-resistance state (in which it is difficult for the current to flow therethrough) is achieved. In contrast, when the magnetization direction of the free layer 53 is in the state parallel with the magnetization direction of the fixed layer 51, a low-resistance state (in which the current can easily flow therethrough) is achieved. Note that the arrangement of the fixed layer 51 and the free layer 53 may be inverted. That is, the intermediate electrode 30, the free layer 53, the tunnel layer 52, the fixed layer 51, and the upper electrode 20 may be stacked in this order.

Next, the operation and advantageous effects of the storage device of the first embodiment will be described.

As described above, in the storage device of the first embodiment, by changing the magnetization direction of the free layer 53, the resistance of the resistive layer 50 changes. When the magnetization direction of the free layer 53 is in the state antiparallel with the magnetization direction of the fixed layer 51, the high-resistance state is achieved. In contrast, when the magnetization direction of the free layer 53 is in the state parallel with the magnetization direction of the fixed layer 51, the low-resistance state is achieved.

For example, the high-resistance state of the resistive layer 50 is defined as data “1”, and the low-resistance state is defined as data “0”. The memory cell MC can maintain the different resistance states, thus allowing one-bit data of “0” and “1” to be stored. Writing into one memory cell MC is performed by applying a voltage and causing current to flow between the bit line 103 and the word line 102 that are connected to the memory cell MC.

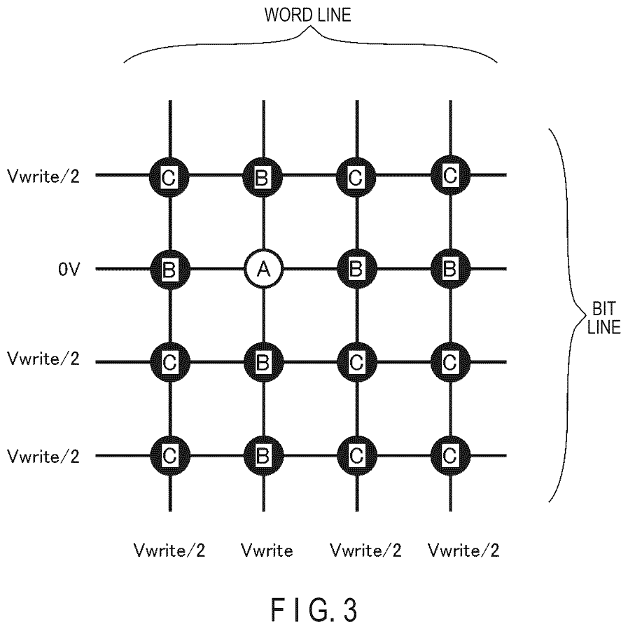

FIG. 3 is a diagram illustrating a problem of the storage device of the first embodiment. FIG. 3 shows the voltage applied to the memory cell MC when one memory cell MC in the memory cell array is selected for a write operation. The intersections of the word lines and the bit lines indicate the respective memory cells MC.

The selected memory cell MC is depicted as memory cell A (selected cell). A write voltage Vwrite is applied to the word line connected to the memory cell A. 0 V is applied to the bit line connected to the memory cell A.

Hereinafter, description is made using an example in which a half voltage of the write voltage (Vwrite/2) is applied to word lines and bit lines that are not connected to the memory cell A.

The voltage applied to memory cells C (which are non-selected cells) connected to the word lines and the bit lines that are not connected to the memory cell A is 0 V. That is, no voltage is applied.

On the other hand, the half voltage of the write voltage Vwrite (Vwrite/2) is applied to memory cells B (hereinafter referred to as semi-selected cells) connected to the word lines or the bit lines connected to the memory cell A. Consequently, leakage current flows through the memory cells B (semi-selected cells). Such leakage current may be referred to as a semi-selected leakage current hereafter.

Note that as an application scheme other than the above, a scheme may be used that applies the half voltage of the write voltage (Vwrite/2) to the word line connected to the memory cell A, applies the half negative voltage of the write voltage (-Vwrite/2) to the bit line, and applies 0 V to word lines and bit lines that are not connected to the memory cell A.

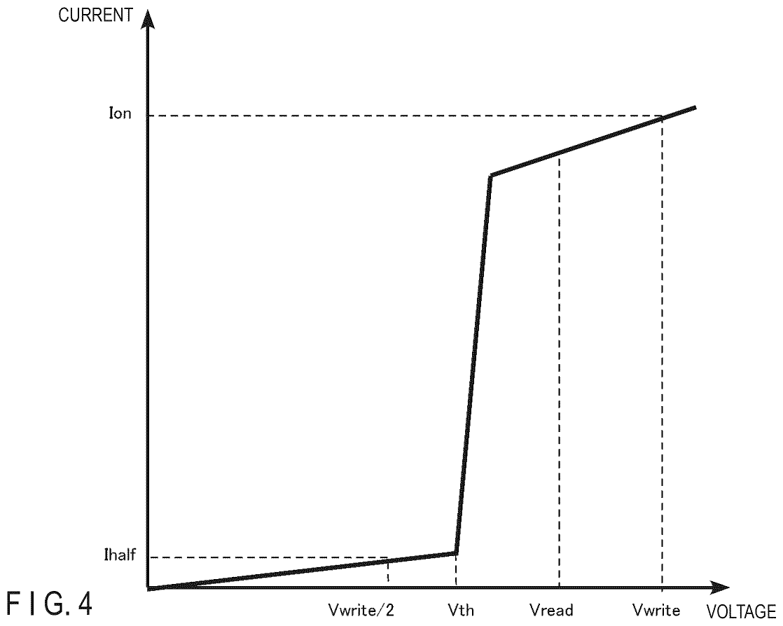

FIG. 4 is a diagram illustrating the current-voltage characteristics of the switching element in the storage device of the first embodiment. The horizontal axis (abscissa) indicates the voltage applied to the switching element, and the vertical (ordinate) indicates the current flowing through the switching element.

The switching element has nonlinear current-voltage characteristics in which the current steeply rises at a threshold voltage Vth. The threshold voltage Vth ranges, for example, between 0.5 V and 3 V, inclusive.

The write voltage Vwrite is set such that the write voltage Vwrite is higher than the threshold voltage Vth, and the half voltage of the write voltage Vwrite (Vwrite/2) is lower than the threshold voltage. The current flowing through the switching element when the write voltage Vwrite is applied is an on-state current (Ion in FIG. 4). The current flowing through the switching element when the half voltage of the write voltage Vwrite (Vwrite/2) is applied is the semi-selected leakage current (Ihalf in FIG. 4).

Note that for example, as shown in FIG. 4, a read voltage Vread to the memory cell MC is set to a voltage higher than the threshold voltage Vth and lower than the write voltage Vwrite. Consequently, the semi-selected leakage current flowing through the semi-selected cells during reading from the memory cell MC can be prevented.

A possible high semi-selected leakage current increases the chip power consumption, for example. For example, the voltage drop in the line increases, and a sufficiently high voltage is not applied to the selected cell, thus making the write operation to the memory cell MC unstable. If the on-state current is low, for example, the current flowing through the selected cell becomes insufficient, thus causing insufficient writing to the memory cell MC. Consequently, the current-voltage characteristics of the switching element are required to achieve both a low semi-selected leakage current and a high on-state current.

Furthermore, in the switching element, a reduction of what is called a first fire voltage is required. The first fire voltage is a high voltage that is applied to the switching element at least once after it is manufactured, in order to activate its function as a switching element. By applying the first fire voltage, a conductive path is formed in the switching element, thereby enabling the switching element to function.

If a high first fire voltage is required to be applied to the switching element to activate its function as a switching element, there is a possibility that, for example, a high current flows through the resistive element, and the characteristics of the resistive element become degraded. Also, if a high first fire voltage is required, the size of the elements of the peripheral circuit is required to be increased to handle the high voltage, for example, thereby hindering the miniaturization of the storage device.

The switching element is required to achieve both a low semi-selected leakage current and a low first fire voltage.

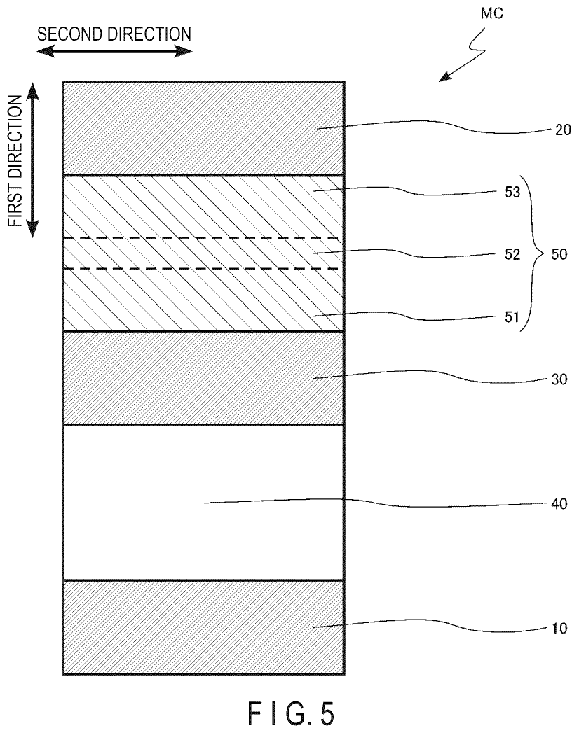

FIG. 5 is a schematic sectional view of a memory cell of a storage device of a comparative example. FIG. 5 is a diagram corresponding to FIG. 2 of the first embodiment.

The storage device of the comparative example is different from the storage device of the first embodiment in that the switching layer 40 does not include the inner region 41 and the side wall region 42.

Similar to the storage device of the first embodiment, the switching layer 40 of the storage device of the comparative example includes the oxide of the first element, the second element, and the third element.

The inventors' discussion has identified that in the storage device of the comparative example, the increase in the sum of the atomic concentration of the second element and the atomic concentration of the third element increases the semi-selected leakage current, and the reduction in the sum of the atomic concentration of the second element and the atomic concentration of the third element requires a high first fire voltage. In other words, it has been identified that a trade-off exists between a low semi-selected leakage current and a low first fire voltage, and it is difficult to achieve both.

The switching layer 40 of the storage device of the first embodiment includes the inner region 41 and the side wall regions 42. The sum of the atomic concentration of the second element and the atomic concentration of the third element in the side wall region 42 is greater than the sum of the atomic concentration of the second element and the atomic concentration of the third element in the inner region 41. In other words, the sum of the atomic concentration of the second element and the atomic concentration of the third element in the inner region 41 is less than the sum of the atomic concentration of the second element and the atomic concentration of the third element in the side wall region 42.

The switching layer 40 includes the inner region 41 where the sum of the atomic concentration of the second element and the atomic concentration of the third element is small, which can realize a low semi-selected leakage current. The switching layer 40 includes the side wall regions 42 where the sum of the atomic concentration of the second element and the atomic concentration of the third element is large, which can realize a low first fire voltage. Consequently, according to the storage device of the first embodiment, both a low semi-selected leakage current and a low first fire voltage can be achieved.

A second sum of the atomic concentration of the second element and the atomic concentration of the third element in the first side wall region 42a is greater than a first sum of the atomic concentration of the second element and the atomic concentration of the third element in the inner region 41.

In view of achieving both a low semi-selected leakage current and a low first fire voltage, it is preferable that the difference between the second sum and the first sum be equal to or greater than 1%, more preferably, equal to or greater than 5%, and further preferably, equal to or greater than 10%. In view of achieving both a low semi-selected leakage current and a low first fire voltage, it is preferable that the second sum be equal to or greater than 1.2 times the first sum, more preferably, equal to or greater than 1.5 times, and further preferably, equal to or greater than twice.

A third sum of the atomic concentration of the second element and the atomic concentration of the third element in the second side wall region 42b is greater than the first sum of the atomic concentration of the second element and the atomic concentration of the third element in the inner region 41.

In view of achieving both a low semi-selected leakage current and a low first fire voltage, it is preferable that the difference between the third sum and the first sum be equal to or greater than 1%, more preferably, equal to or greater than 5%, and further preferably, equal to or greater than 10%. In view of achieving both a low semi-selected leakage current and a low first fire voltage, it is preferable that the third sum be equal to or greater than 1.2 times the first sum, more preferably, equal to or greater than 1.5 times, and further preferably, equal to or greater than twice.

In view of achieving both a low semi-selected leakage current and a low first fire voltage, it is preferable that the concentration of the compound of the second element and the third element in the side wall region 42 be greater than the concentration of the compound of the second element and the third element in the inner region 41.

In view of achieving both a low semi-selected leakage current and a low first fire voltage, it is preferable that the electrical resistivity in the side wall region 42 be less than the first electrical resistivity in the inner region 41. In view of achieving both a low semi-selected leakage current and a low first fire voltage, it is preferable that the second electrical resistivity in the first side wall region 42a be less than the first electrical resistivity in the inner region 41. In view of achieving both a low semi-selected leakage current and a low first fire voltage, it is preferable that the third electrical resistivity in the second side wall region 42b be less than the first electrical resistivity in the inner region 41.

Preferably, the switching layer 40 contains at least one fourth element selected from a group consisting of carbon (C), boron (B), phosphorus (P), and nitrogen (N). The switching layer 40 contains the fourth element, which prevents the switching layer 40 from being crystallized, and reduces the semi-selected leakage current, for example.

According to the first embodiment, the switching element having a low semi-selected leakage current and a low first fire voltage can be realized. Consequently, according to the first embodiment, the storage device that includes the switching element with excellent characteristics can be realized.

### (First Modification)

The storage device according to a first modification of the first embodiment is different from the storage device of the first embodiment in that the first conductive layer includes a first portion and a second portion, and the first portion contains at least one element selected from among hafnium (Hf), aluminum (Al), magnesium (Mg), zirconium (Zr), and titanium (Ti).

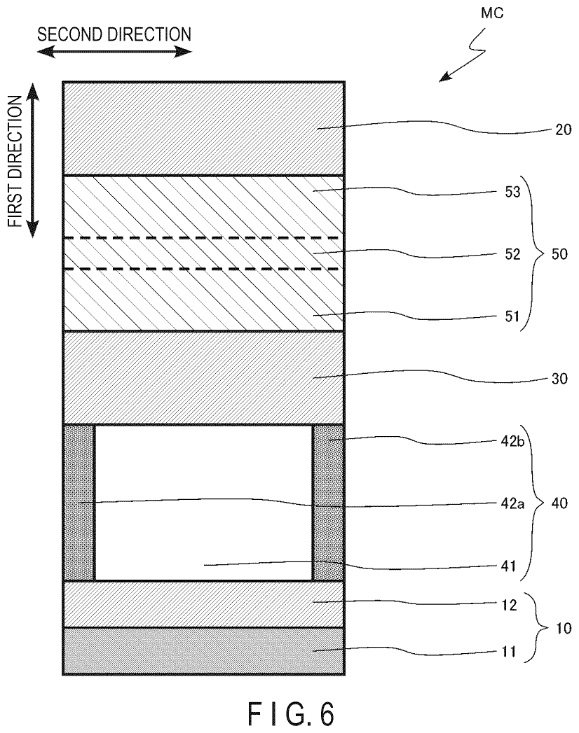

FIG. 6 is a schematic sectional view of a memory cell of the storage device according to the first modification of the first embodiment. FIG. 6 is a diagram corresponding to FIG. 2 according to the first embodiment.

The lower electrode 10 includes a first portion 11, and a second portion 12. The second portion 12 is provided between the first portion 11 and the switching layer 40.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 contains, for example, at least one substance selected from a group consisting of carbon, carbon nitride, tungsten, tungsten carbide, tungsten nitride, titanium, titanium nitride, tantalum, tantalum carbide, and tantalum nitride.

In the storage device according to the first modification of the first embodiment, the first portion 11 of the lower electrode 10 contains at least one element selected from among hafnium (Hf), aluminum (Al), magnesium (Mg), zirconium (Zr), and titanium (Ti), so that the characteristics of the resistive element can be prevented from being degraded. Since the first portion 11 is not in contact with the switching layer 40, desorption of oxygen (O) from the switching layer 40 can be prevented, thus preventing the characteristics of the switching element from being degraded.

As described above, similar to the first embodiment, according to the first modification of the first embodiment, the storage device that includes the switching element with excellent characteristics can be realized.

### (Second Modification)

A storage device according to a second modification of the first embodiment is different from the storage device of the first embodiment in that a first conductive layer includes a first portion and a second portion, and the first portion contains at least one element selected from among hafnium (Hf), aluminum (Al), magnesium (Mg), zirconium (Zr), and titanium (Ti), the second conductive layer contains one element selected from among hafnium (Hf), aluminum (Al), magnesium (Mg), zirconium (Zr), and titanium (Ti), the third conductive layer includes a third portion and a fourth portion, and the fourth portion contains at least one element selected from among hafnium (Hf), aluminum (Al), magnesium (Mg), zirconium (Zr), and titanium (Ti).

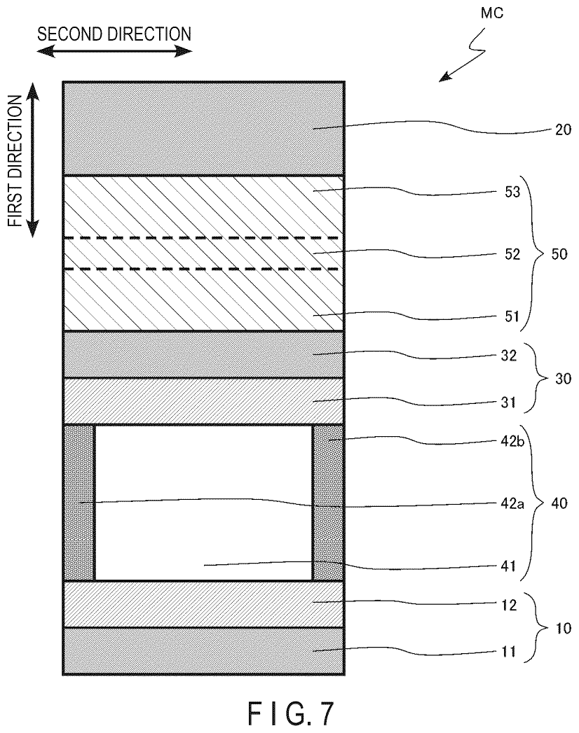

FIG. 7 is a schematic sectional view of a memory cell of the storage device according to the second modification of the first embodiment. FIG. 7 is a diagram corresponding to FIG. 2 of the first embodiment.

The lower electrode 10 includes a first portion 11, and a second portion 12. The second portion 12 is provided between the first portion 11 and the switching layer 40.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 contains, for example, at least one substance selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from among hafnium (Hf), aluminum (Al), magnesium (Mg), zirconium (Zr), and titanium (Ti). The upper electrode 20 contains, for example, a boride of the element described above. The upper electrode 20 contains, for example, at least one substance selected from a group consisting of hafnium, hafnium boride, magnesium aluminum boride, zirconium, zirconium boride, and titanium boride.

The intermediate electrode 30 includes a third portion 31, and a fourth portion 32. The third portion 31 is provided between the fourth portion 32 and the switching layer 40.

The third portion 31 contains, for example, at least one substance selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from among hafnium (Hf), aluminum (Al), magnesium (Mg), zirconium (Zr), and titanium (Ti). The fourth portion 32 contains, for example, a boride of the element described above. The fourth portion 32 contains, for example, at least one substance selected from a group consisting of hafnium, hafnium boride, magnesium aluminum boride, zirconium, zirconium boride, and titanium boride.

In the storage device according to the second modification of the first embodiment, the first portion 11 of the lower electrode 10, the upper electrode 20, and the fourth portion 32 of the intermediate electrode 30 contain at least one element selected from among hafnium (Hf), aluminum (Al), magnesium (Mg), zirconium (Zr), and titanium (Ti), so that the characteristics of the resistive element can be prevented from being degraded. The first portion 11 of the lower electrode 10, the upper electrode 20, and the fourth portion 32 of the intermediate electrode 30 are not in contact with the switching layer 40, so that desorption of oxygen (O) from the switching layer 40 can be prevented, thus preventing the characteristics of the switching element from being degraded.

As described above, similar to the first embodiment, according to the second modification of the first embodiment, the storage device that includes the switching element with excellent characteristics can be realized.

### (Third Modification)

A storage device according to a third modification of the first embodiment is different from the storage device of the first embodiment in that a first conductive layer includes a first portion, a second portion, and a fifth portion, and the first portion contains at least one element selected from among hafnium (Hf), aluminum (Al), magnesium (Mg), zirconium (Zr), and titanium (Ti), the second conductive layer contains one element selected from among hafnium (Hf), aluminum (Al), magnesium (Mg), zirconium (Zr), and titanium (Ti), the third conductive layer includes a third portion and a fourth portion, and the fourth portion contains at least one element selected from among hafnium (Hf), aluminum (Al), magnesium (Mg), zirconium (Zr), and titanium (Ti).

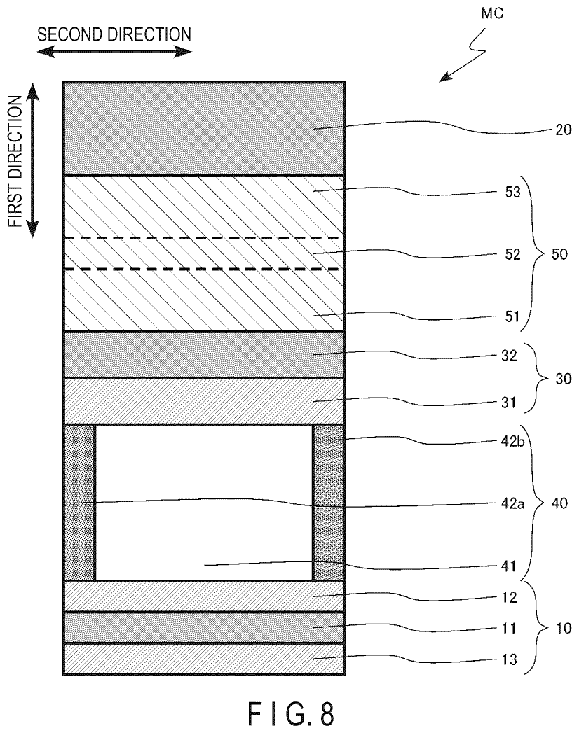

FIG. 8 is a schematic sectional view of a memory cell of the storage device according to the third modification of the first embodiment. FIG. 8 is a diagram corresponding to FIG. 2 of the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 and the fifth portion 13 contain, for example, at least one substance selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from among hafnium (Hf), aluminum (Al), magnesium (Mg), zirconium (Zr), and titanium (Ti). The upper electrode 20 contains, for example, a boride of the element described above. The upper electrode 20 contains, for example, at least one substance selected from a group consisting of hafnium, hafnium boride, magnesium aluminum boride, zirconium, zirconium boride, and titanium boride.

The intermediate electrode 30 includes a third portion 31, and a fourth portion 32. The third portion 31 is provided between the fourth portion 32 and the switching layer 40.

The third portion 31 contains, for example, at least one substance selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from among hafnium (Hf), aluminum (Al), magnesium (Mg), zirconium (Zr), and titanium (Ti). The fourth portion 32 contains, for example, a boride of the element described above. The fourth portion 32 contains, for example, at least one substance selected from a group consisting of hafnium, hafnium boride, magnesium aluminum boride, zirconium, zirconium boride, and titanium boride.

In the storage device according to the third modification of the first embodiment, the first portion 11 of the lower electrode 10, the upper electrode 20, and the fourth portion 32 of the intermediate electrode 30 contain at least one element selected from among hafnium (Hf), aluminum (Al), magnesium (Mg), zirconium (Zr), and titanium (Ti), so that the characteristics of the resistive element can be prevented from being degraded. The first portion 11 of the lower electrode 10, the upper electrode 20, the fourth portion 32 of the intermediate electrode 30 are not in contact with the switching layer 40, so that desorption of oxygen (O) from the switching layer 40 can be prevented, thus preventing the characteristics of the switching element from being degraded.

As described above, similar to the first embodiment, according to the third modification of the first embodiment, the storage device that includes the switching element with excellent characteristics can be realized.

### (Fourth Modification)

A storage device according to a fourth modification of the first embodiment is different from the storage device of the first embodiment in that the first conductive layer or the third conductive layer includes a carbon layer and a metal layer, and the carbon layer is provided between the metal layer and the switching layer.

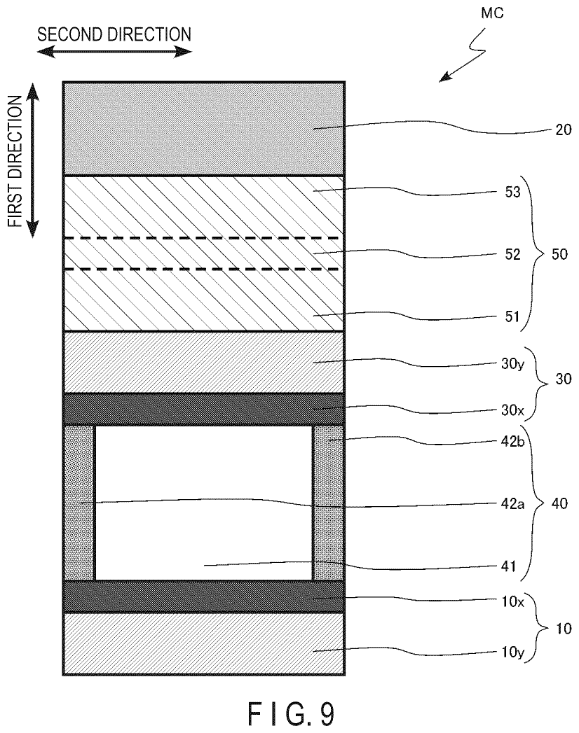

FIG. 9 is a schematic sectional view of a memory cell of the storage device according to the fourth modification of the first embodiment. FIG. 9 is a diagram corresponding to FIG. 2 of the first embodiment.

The lower electrode 10 includes a first carbon layer 10x and a first metal layer 10y. The first carbon layer 10x is provided between the first metal layer 10y and the switching layer 40. The first carbon layer 10x is an example of the carbon layer. The first metal layer 10y is an example of the metal layer.

The first carbon layer 10x contains carbon (C). The first carbon layer 10x contains, for example, graphite.

The first metal layer 10y contains metal. The first metal layer 10y contains, for example, tungsten (W), tin (Sn), molybdenum (Mo), or germanium (Ge).

The intermediate electrode 30 includes a second carbon layer 30x and a second metal layer 30y. The second carbon layer 30x provided between the second metal layer 30y and the switching layer 40 is an example of the carbon layer. The second metal layer 30y is an example of the metal layer.

The second carbon layer 30x contains carbon (C). The second carbon layer 30x contains, for example, graphite.

The second metal layer 30y contains metal. The second metal layer 30y contains, for example, tungsten (W), tin (Sn), molybdenum (Mo), or germanium (Ge).

As described above, similar to the first embodiment, according to the fourth modification of the first embodiment, the storage device that includes the switching element with excellent characteristics can be realized.

According to the first embodiment and its modifications, the switching element having a low semi-selected leakage current and a low first fire voltage can be realized. Consequently, according to the first embodiment, the storage device that includes the switching element with excellent characteristics can be realized.

### Second Embodiment

A storage device of a second embodiment is different from the storage device of the first embodiment in that the switching layer further includes a fourth region provided between the first region and the first conductive layer, and a fourth sum of the atomic concentration of the second element and the atomic concentration of the third element in the fourth region is greater than the first sum. Hereinafter, portions of the description that are redundant with the first embodiment may be omitted.

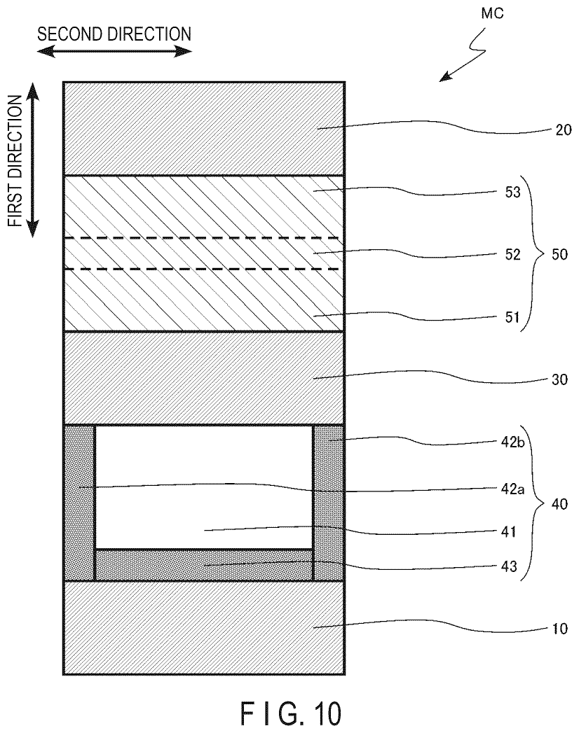

FIG. 10 is a schematic sectional view of a memory cell of the storage device of the second embodiment. FIG. 10 is a diagram corresponding to FIG. 2 of the first embodiment.

As shown in FIG. 10, the memory cell MC includes a lower electrode 10, an upper electrode 20, an intermediate electrode 30, a switching layer 40, and a resistive layer 50. The switching layer 40 includes an inner region 41, a first side wall region 42a, a second side wall region 42b, and a lower region 43. Hereinafter, the first side wall region 42a and the second side wall region 42b are individually or collectively called a side wall region 42. The resistive layer 50 includes a fixed layer 51, a tunnel layer 52, and a free layer 53.

The lower electrode 10 is an example of a first conductive layer. The upper electrode 20 is an example of a second conductive layer. The intermediate electrode 30 is an example of a third conductive layer. The inner region 41 is an example of the first region. The first side wall region 42a is an example of the second region. The second side wall region 42b is an example of the third region. The lower region 43 is an example of the fourth region.

The switching layer 40 includes the inner region 41, the side wall region 42, and the lower region 43. The side wall region 42 includes the first side wall region 42a, and the second side wall region 42b.

The lower region 43 is provided between the inner region 41 and the lower electrode 10.

The lower region 43 includes the second element and the third element. The lower region 43 includes, for example, a compound of the second element and the third element.

The lower region 43 may or may not include the first oxide. The lower region 43 includes, for example, the first oxide.

The fourth sum of the atomic concentration of the second element and the atomic concentration of the third element in the lower region 43 is greater than the first sum of the atomic concentration of the second element and the atomic concentration of the third element in the inner region 41. The difference between the fourth sum and the first sum ranges between, for example, 1% and 50%, inclusive. The fourth sum is, for example, equal to or greater than 1.2 times and equal to or less than 5 times the first sum.

The ratio of the sum of the atomic concentration of the second element and the atomic concentration of the third element to the sum of the atomic concentration of the first element, the atomic concentration of the second element, the atomic concentration of the third element, and the atomic concentration of oxygen in the lower region 43 is greater than, for example, the ratio of the sum of the atomic concentration of the second element and the atomic concentration of the third element to the sum of the atomic concentration of the first element, the atomic concentration of the second element, the atomic concentration of the third element, and the atomic concentration of oxygen in the inner region 41.

The atomic concentration of the second element in the lower region 43 is greater than, for example, the atomic concentration of the second element in the inner region 41. The atomic concentration of the third element in the lower region 43 is greater than, for example, the atomic concentration of the third element in the inner region 41.

The concentration of the compound of the second element and the third element in the lower region 43 is greater than, for example, the concentration of the compound of the second element and the third element in the inner region 41.

The density of chemical bonds between the second element and the third element in the lower region 43 is greater than, for example, the density of chemical bonds between the second element and the third element in the inner region 41.

A fourth electrical resistivity in the lower region 43 is less than, for example, the first electrical resistivity in the inner region 41.

The thickness of the lower region 43 in the first direction is less than, for example, the thickness of the inner region 41 in the first direction. The thickness of the lower region 43 in the first direction ranges between, for example, 1 nm and 5 nm, inclusive.

Next, a method of manufacturing the memory cell of the storage device of the second embodiment will be described.

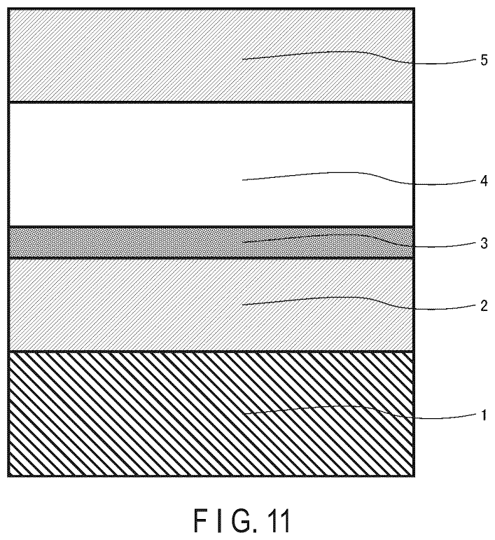

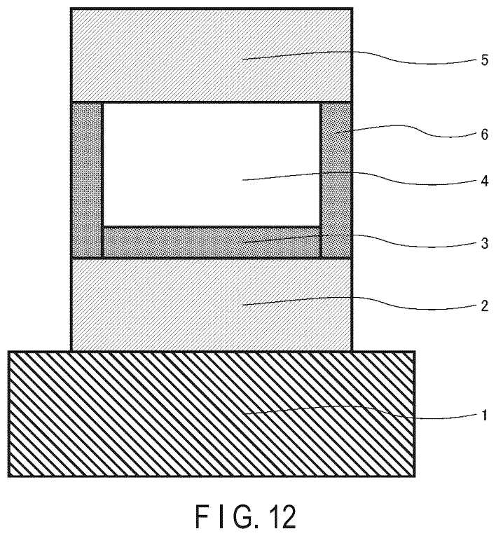

FIGS. 11 and 12 are schematic sectional views showing the method of manufacturing the memory cell of the storage device of the second embodiment. FIGS. 11 and 12 are cross-sections corresponding to FIG. 10.

A case where the first element is zirconium (Zr), the second element is zinc (Zn), and the third element is tellurium (Te) will be described below as an example.

First, a first carbon film 2, a first zirconium oxide film 3 that contains zinc (Zn) and tellurium (Te), a second zirconium oxide film 4 that contains zinc (Zn) and tellurium (Te), and a second carbon film 5 are formed on a substrate 1 (FIG. 11). The atomic concentration of zinc and the atomic concentration of tellurium contained in the first zirconium oxide film 3 are respectively greater than the atomic concentration of zinc and the atomic concentration of tellurium contained in the second zirconium oxide film 4.

The substrate 1 is, for example, a conductive layer. The first carbon film 2, the first zirconium oxide film 3, the second zirconium oxide film 4, and the second carbon film 5 are formed by, for example, a sputtering method. The first carbon film 2, the first zirconium oxide film 3, the second zirconium oxide film 4, and the second carbon film 5 are finally formed as the lower electrode 10, the lower region 43, the inner region 41, and the intermediate electrode 30, respectively.

Next, a resist pattern, not shown, is formed on the second carbon film 5 using a lithography method. Next, with the resist as a mask, reactive ion etching (RIE) is performed, and the second carbon film 5, the second zirconium oxide film 4, the first zirconium oxide film 3, and the first carbon film 2 are processed (FIG. 12).

During RIE, the etched first zirconium oxide film 3 adheres again to the side surface of the second zirconium oxide film 4, and a third zirconium oxide film 6 is formed. The third zirconium oxide film 6 contains zinc (Zn) and tellurium (Te). The third zirconium oxide film 6 is finally formed as the side wall region 42. The atomic concentration of zinc and the atomic concentration of tellurium contained in the third zirconium oxide film 6 are respectively greater than the atomic concentration of zinc and the atomic concentration of tellurium contained in the second zirconium oxide film 4.

Subsequently, by a well-known manufacturing method, the resistive layer 50 and the upper electrode 20 are formed. By the manufacturing method described above, the memory cell of the storage device of the second embodiment is formed.

As described above, according to the second embodiment, the switching layer 40 includes the inner region 41 and the side wall region 42, which can realize the switching element that has a low semi-selected leakage current and a low first fire voltage, in a manner similar to that in the first embodiment. Consequently, according to the second embodiment, the storage device that includes the switching element with excellent characteristics can be realized.

According to the second embodiment, the switching layer 40 includes the lower region 43, thereby allowing the side wall region 42 to be easily formed.

### Third Embodiment

A storage device according to a third embodiment includes a memory cell that includes: a first conductive layer; a second conductive layer; a third conductive layer provided between the first conductive layer and the second conductive layer; a switching layer provided between the first conductive layer and the third conductive layer; and a resistive layer provided between the third conductive layer and the second conductive layer. The switching layer contains: a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the at least one first element and is selected from a group consisting of aluminum (Al), zinc (Zn), tin (Sn), gallium (Ga), indium (In), and bismuth (Bi); and at least one third element selected from a group consisting of tellurium (Te), sulfur (S), selenium (Se), and antimony (Sb). The switching layer includes a first region, a second region, and a third region in a cross-section parallel to a first direction connecting the first conductive layer and the second conductive layer, and the first region is provided in the cross-section between the second region and the third region in a second direction perpendicular to the first direction. The first region includes the first oxide; the second region and the third region include the second element and the third element; a second density of bonds between the third element and the third element in the second region is greater than a first density of bonds between the third element and the third element in the first region; and a third density of bonds between the third element and the third element in the third region is greater than the first density.

The storage device of the third embodiment is different from the storage device of the first embodiment in that the second density of bonds between the third element and the third element in the second region is greater than the first density of bonds between the third element and the third element in the first region, and the third density of bonds between the third element and the third element in the third region is greater than the first density. Hereinafter, portions the description that are redundant with the first embodiment may be omitted.

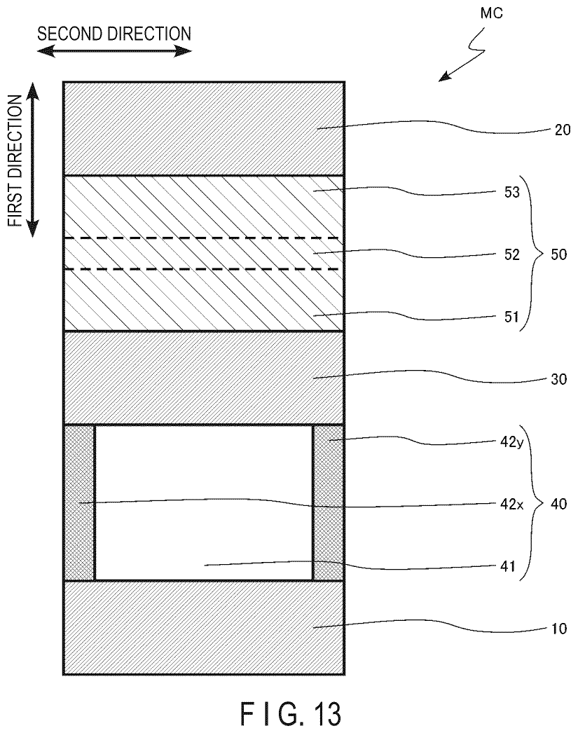

FIG. 13 is a schematic sectional view of the memory cell of the storage device of the third embodiment. FIG. 13 corresponds to FIG. 2 of the first embodiment.

As shown in FIG. 13, the memory cell MC includes a lower electrode 10, an upper electrode 20, an intermediate electrode 30, a switching layer 40, and a resistive layer 50. The switching layer 40 includes an inner region 41, a first side wall region 42x, and a second side wall region 42y. Hereinafter, the first side wall region 42x and the second side wall region 42y are individually or collectively called a side wall region 42. The resistive layer 50 includes a fixed layer 51, a tunnel layer 52, and a free layer 53.

The switching layer 40 is provided between the lower electrode 10 and the intermediate electrode 30. The switching layer 40 is in contact with, for example, the lower electrode 10 and the intermediate electrode 30.

The thickness of the switching layer 40 in the first direction from the lower electrode 10 toward the upper electrode 20 ranges between, for example, 5 nm and 50 nm, inclusive. It is preferable that the thickness of the switching layer 40 in the first direction from the lower electrode 10 toward the upper electrode 20 range between, for example, 5 nm and 20 nm, inclusive. The length of the switching layer 40 in the second direction perpendicular to the first direction ranges between, for example, 10 nm and 50 nm, inclusive.

The switching layer 40 has a function of preventing increase in semi-selected leakage current that flows through a semi-selected cell. The switching layer 40 has nonlinear current-voltage characteristics in which the current steeply rises at a specific threshold voltage.

The switching layer 40 contains the first oxide of the first element, the second element, and the third element.

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg). The first oxide is, for example, aluminum oxide, silicon oxide, germanium oxide, zirconium oxide, yttrium oxide, tantalum oxide, lanthanum oxide, cerium oxide, titanium oxide, hafnium oxide, or magnesium oxide.

The second element is an element different from the first element. The second element is at least one element selected from a group consisting of aluminum(Al), zinc (Zn), tin (Sn), gallium (Ga), indium (In), and bismuth (Bi). The third element is at least one element selected from a group consisting of tellurium (Te), sulfur (S), selenium (Se), and antimony (Sb).

The switching layer 40 contains, for example, a compound of the second element and the third element. The compound of the second element and the third element contains, for example, aluminum telluride, zinc telluride, tin telluride, gallium telluride, indium telluride, bismuth telluride, aluminum sulfide, zinc sulfide, tin sulfide, gallium sulfide, indium sulfide, bismuth sulfide, aluminum selenide, zinc selenide, tin selenide, gallium selenide, indium selenide, bismuth selenide, aluminum antimonide, zinc antimonide, tin antimonide, gallium antimonide, indium antimonide, or bismuth antimonide.

The sum of the atomic concentrations of the first element, the second element, the third element, and oxygen (O) in the switching layer 40 ranges between, for example, 80% and 100%, inclusive.

The ratio of the sum of the atomic concentrations of the first element and oxygen (O) to the sum of the atomic concentrations of the first element, the second element, the third element, and the oxygen (O) in the switching layer 40 ranges between, for example, 5% and 90%, inclusive.

The atomic concentration of the first element contained in the switching layer 40 ranges between, for example, 2% and 30%, inclusive. The atomic concentration of the second element contained in the switching layer 40 ranges between, for example, 5% and 50%, inclusive. The atomic concentration of the third element contained in the switching layer 40 ranges between, for example, 5% and 50%, inclusive. The atomic concentration of oxygen contained in the switching layer 40 ranges between, for example, 4% and 60%, inclusive.

The atomic concentration of the third element contained in the switching layer 40 is, for example, equal to or greater than 0.8 times and equal to or less than 1.2 times the atomic concentration of the second element.

The switching layer 40 contains, for example, at least one fourth element selected from a group consisting of carbon (C), boron (B), phosphorus (P), and nitrogen (N). The atomic concentration of the fourth element contained in the switching layer 40 ranges between, for example, 5% and 20%, inclusive.

The switching layer 40 includes the inner region 41 and the side wall region 42. The side wall region 42 includes the first side wall region 42x, and the second side wall region 42y.

In the second direction that is perpendicular to the first direction in a cross-section parallel to the first direction connecting the lower electrode 10 and the upper electrode 20, the inner region 41 is provided between the first side wall region 42x and the second side wall region 42y. The first side wall region 42x and the second side wall region 42y are provided between, for example, the lower electrode 10 and the intermediate electrode 30 in the first direction. The first side wall region 42x and the second side wall region 42y are provided between, for example, the lower electrode 10 and the intermediate electrode 30 in the first direction.

The inner region 41 includes the first oxide. The inner region 41 may or may not include the second element and the third element. The inner region 41 includes, for example, the second element and the third element.

The inner region 41 includes, for example, a compound of the second element and the third element. The inner region 41 contains, for example, the chemical bond between the second element and the third element.

The inner region 41 may or may not include the chemical bond between the third element and the third element. The density of chemical bonds between the third element and the third element in the inner region 41 is the first density.

The inner region 41 may or may not include a second oxide of the second element.

The side wall region 42 includes the second element and the third element. The first side wall region 42x and the second side wall region 42y include the second element and the third element.

The side wall region 42 may or may not include a compound of the second element and the third element. The side wall region 42 may or may not include the chemical bond between the second element and the third element.

The first side wall region 42x may or may not include a compound of the second element and the third element. The second side wall region 42y may or may not include the chemical bond between the second element and the third element.

The second side wall region 42y may or may not include a compound of the second element and the third element. The second side wall region 42y may or may not include the chemical bond between the second element and the third element.

The side wall region 42 includes the chemical bond between the third element and the third element.

The first side wall region 42x includes the chemical bond between the third element and the third element. The density of chemical bonds between the third element and the third element in the first side wall region 42x is the second density.

The second side wall region 42y includes the chemical bond between the third element and the third element. The density of chemical bonds between the third element and the third element in the second side wall region 42y is the third density.

The side wall region 42 includes, for example, the second oxide of the second element. The first side wall region 42x and the second side wall region 42y include, for example, the second oxide of the second element.

The side wall region 42 may or may not include the first oxide. The first side wall region 42x and the second side wall region 42y may or may not include the first oxide.

The side wall region 42 includes, for example, the first oxide. The first side wall region 42x and the second side wall region 42y include, for example, the first oxide.

The second density of chemical bonds between the third element and the third element in the first side wall region 42x is greater than the first density of chemical bonds between the third element and the third element in the inner region 41. The third density of chemical bonds between the third element and the third element in the second side wall region 42y is greater than the first density.

The second density is, for example, equal to or greater than 1.2 times and equal to or less than 5 times the first density. The third density is, for example, equal to or greater than 1.2 times and equal to or less than 5 times the first density.

The second concentration of the second oxide of the second element in the first side wall region 42x is greater than the first concentration of the second oxide of the second element in the inner region 41. The third concentration of the second oxide of the second element in the second side wall region 42y is greater than the first concentration of the second oxide of the second element in the inner region 41.

The second concentration is, for example, equal to or greater than 1.2 times and equal to or less than 5 times the first concentration. The third concentration is, for example, equal to or greater than 1.2 times and equal to or less than 5 times the first concentration.

The concentration of the compound of the second element and the third element in the side wall region 42 is less than, for example, the concentration of the compound of the second element and the third element in the inner region 41. Note that the concentration of the compound of the second element and the third element is given in molarity, for example.

The density of chemical bonds between the second element and the third element in the side wall region 42 is less than, for example, the density of chemical bonds between the second element and the third element in the inner region 41.

The electrical resistivity in the side wall region 42 is less than, for example, a first electrical resistivity in the inner region 41. The second electrical resistivity in the first side wall region 42x is less than, for example, the first electrical resistivity in the inner region 41. The third electrical resistivity in the second side wall region 42y is less than, for example, the first electrical resistivity in the inner region 41.

The thickness of the side wall region 42 in the second direction ranges between, for example, 1 nm and 5 nm, inclusive. The thickness of the first side wall region 42x in the second direction ranges between, for example, 1 nm and 5 nm, inclusive. The thickness of the second side wall region 42y in the second direction ranges between, for example, 1 nm and 5 nm, inclusive.

The thickness of the side wall region 42 in the second direction is less than, for example, the thickness of the inner region 41 in the second direction. The thickness of the side wall region 42 in the second direction is equal to or less than, for example, one-half the thickness of the inner region 41 in the second direction.

Next, a method of manufacturing the memory cell of the storage device of the third embodiment will be described.

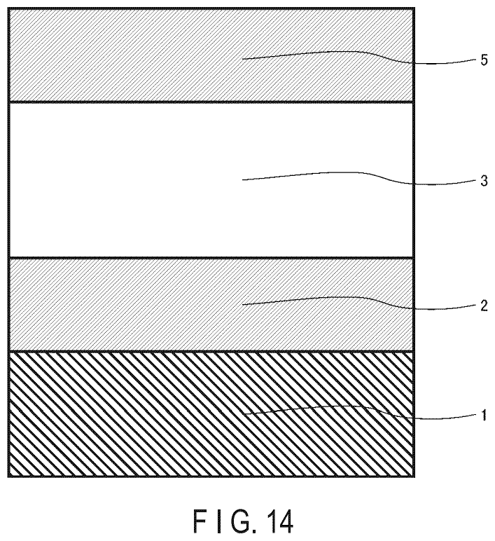

FIGS. 14, 15, 16, and 17 are schematic sectional views showing the method of manufacturing the memory cell of the storage device of the third embodiment. FIGS. 14 to 17 are cross-sections corresponding to FIG. 13.

A case where the first element is zirconium (Zr), the second element is zinc (Zn), and the third element is tellurium (Te) will be described below as an example.

First, a first carbon film 2, a first zirconium oxide film 3 that contains zinc (Zn) and tellurium (Te), and a second carbon film 5 are formed on a substrate 1 (FIG. 14). The first zirconium oxide film 3 contains zinc telluride, which is a compound of zinc (Zn) and tellurium (Te).

The substrate 1 is, for example, a conductive layer. The first carbon film 2, the first zirconium oxide film 3, and the second carbon film 5 are formed by, for example, the sputtering method. The first carbon film 2, the first zirconium oxide film 3, and the second carbon film 5 are finally formed as the lower electrode 10, the switching layer 40, and the intermediate electrode 30, respectively.

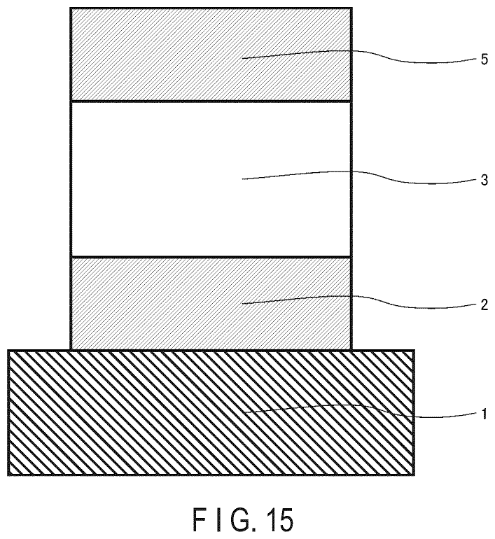

Next, a resist pattern, not shown, is formed on the second carbon film 5 using a lithography method. Next, with the resist as a mask, reactive ion etching (RIE) is performed, and the second carbon film 5, the first zirconium oxide film 3, and the first carbon film 2 are processed (FIG. 15).

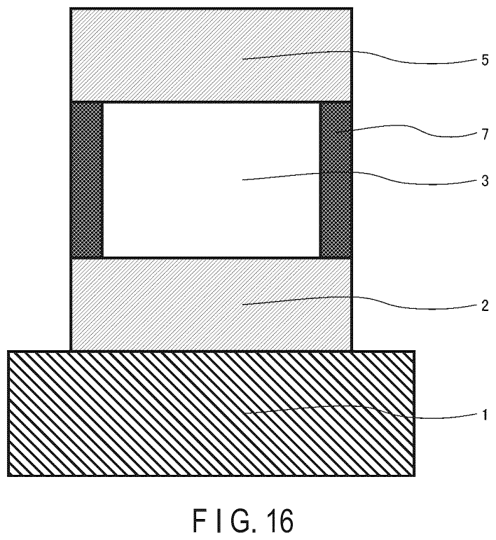

Next, an oxidation treatment that oxides the side surface of the first zirconium oxide film 3 is performed (FIG. 16). The oxidation treatment is, for example, thermal oxidation.

By the oxidation treatment, an oxidized region 7 is formed on the side surface of the first zirconium oxide film 3. For example, zinc oxide and tellurium oxide are formed in the oxidized region 7. By the oxidation treatment, for example, zinc telluride is decomposed, and zinc oxide and tellurium oxide are formed.

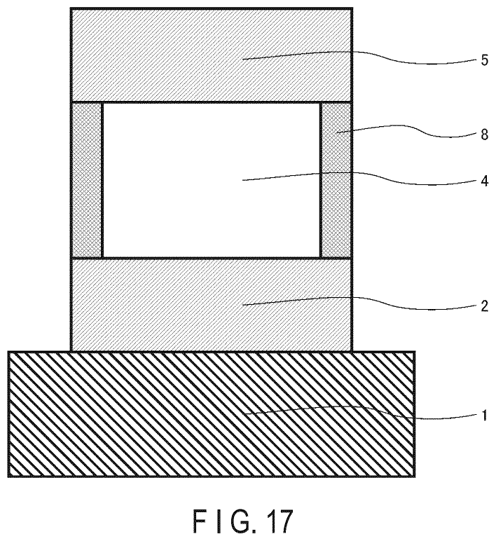

Next, a reduction treatment that reduces the side surface of the first zirconium oxide film 3 is performed (FIG. 17). The reduction treatment is, for example, hydrogen anneal.

By the reduction treatment, a reduced region 8 is formed on the side surface of the first zirconium oxide film 3. The reduced region 8 is finally formed as the side wall region 42.

By the reduction treatment, for example, tellurium oxide is reduced, and the chemical bonds between tellurium atoms and tellurium atoms, i.e., tellurium-tellurium bonds, are formed.

Note that the oxide standard generation energy of tellurium is greater than the oxide standard generation energy of zinc. Thus, zinc oxidizes are more readily oxidized than tellurium. In other words, tellurium oxide is reduced more readily than zinc oxide. Accordingly, the reduction of tellurium oxide in the oxidized region 7 is more readily achieved than the reduction of zinc oxide, and tellurium-tellurium bonds are formed in the reduced region 8. Zinc oxide remains in the reduced region 8.

Subsequently, by a well-known manufacturing method, the resistive layer 50 and the upper electrode 20 are formed. By the manufacturing method described above, the memory cell of the storage device of the third embodiment is formed.

Next, the operation and advantageous effects of the storage device of the third embodiment will be described.

According to the storage device of the third embodiment, similar to the storage device of the first embodiment, the memory cell MC includes the resistive layer 50, which can store data.

Similar to the switching element of the storage device of the first embodiment, the switching element of the storage device of the third embodiment has nonlinear current-voltage characteristics in which the current steeply rises at the threshold voltage Vth.

As described in detail in the first embodiment, the switching element is required to achieve both a low semi-selected leakage current and a low first fire voltage.

The switching layer 40 of the storage device of the third embodiment includes the inner region 41 and the side wall region 42. The side wall region 42 includes the chemical bond between the third element and the third element, which can reduce the electrical resistivity in the side wall region 42, and realize a low first fire voltage. The density of the chemical bonds between the third element and the third element in the inner region 41 is less than the density of the chemical bonds between the third element and the third element in the side wall region 42, which can increase the electrical resistivity in the inner region 41, and realize a low semi-selected leakage current. Consequently, according to the storage device of the third embodiment, both a low semi-selected leakage current and a low first fire voltage can be achieved.

In view of achieving both a low semi-selected leakage current and a low first fire voltage, it is preferable that the second density of chemical bonds between the third element and the third element in the first side wall region 42x be equal to or greater than 1.2 times the first density of chemical bonds between the third element and the third element in the inner region 41, preferably, equal to or greater than 1.5 times, and further preferably, equal to or greater than twice.

In view of achieving both a low semi-selected leakage current and a low first fire voltage, it is preferable that the third density of chemical bonds between the third element and the third element in the second side wall region 42y be equal to or greater than 1.2 times the first density of chemical bonds between the third element and the third element in the inner region 41, preferably, equal to or greater than 1.5 times, and further preferably, equal to or greater than twice.

In view of achieving both a low semi-selected leakage current and a low first fire voltage, it is preferable that the first side wall region 42x contain the second oxide of the second element. The first side wall region 42x contains the second oxide of the second element, which can prevent the semi-selected leakage current from increasing.

In view of achieving both a low semi-selected leakage current and a low first fire voltage, it is preferable that the second concentration of the second oxide of the second element in the first side wall region 42x be greater than the first concentration of the second oxide of the second element in the inner region 41. In view of achieving both a low semi-selected leakage current and a low first fire voltage, it is preferable that the second concentration be, for example, equal to or greater than 1.2 times the first concentration, preferably, equal to or greater than 1.5 times, and further preferably, equal to or greater than twice.

In view of achieving both a low semi-selected leakage current and a low first fire voltage, it is preferable that the second side wall region 42y contain the second oxide of the second element. The second side wall region 42y contains the second oxide of the second element, which can prevent the semi-selected leakage current from increasing.

In view of achieving both a low semi-selected leakage current and a low first fire voltage, it is preferable that the third concentration of the second oxide of the second element in the second side wall region 42y be greater than the first concentration of the second oxide of the second element in the inner region 41. In view of achieving both a low semi-selected leakage current and a low first fire voltage, it is preferable that the third concentration be, for example, equal to or greater than 1.2 times the first concentration, preferably, equal to or greater than 1.5 times, and further preferably, equal to or greater than twice.

In view of achieving both a low semi-selected leakage current and a low first fire voltage, it is preferable that the concentration of the compound of the second element and the third element in the side wall region 42 be less than the concentration of the compound of the second element and the third element in the inner region 41.

As described above, when the side wall region 42 is formed, the compound of the second element and the third element is decomposed by the oxidation treatment, and the second oxide of the second element and a third oxide of the third element are formed. Subsequently, the third oxide is reduced by the reduction treatment, and the chemical bond between the third element and the third element is formed. Consequently, as the density of chemical bonds between the third element and the third element in the side wall region 42 increases, the concentration of the compound of the second element and the third element in the side wall region 42 decreases. As the density of chemical bonds between the third element and the third element in the side wall region 42 increases, the concentration of the compound of the second element and the third element in the side wall region 42 becomes less than the concentration of the compound of the second element and the third element in the inner region 41. In other words, as the density of chemical bonds between the third element and the third element in the side wall region 42 is greater than the density of chemical bonds between the third element and the third element in the inner region 41, the concentration of the compound of the second element and the third element in the side wall region 42 is less than the concentration of the compound of the second element and the third element in the inner region 41.

In view of achieving both a low semi-selected leakage current and a low first fire voltage, it is preferable that the density of chemical bonds between the second element and the third element in the side wall region 42 be less than, for example, the density of chemical bonds between the second element and the third element in the inner region 41.

In view of achieving both a low semi-selected leakage current and a low first fire voltage, it is preferable that the electrical resistivity in the side wall region 42 be less than the first electrical resistivity in the inner region 41. In view of achieving both a low semi-selected leakage current and a low first fire voltage, it is preferable that the second electrical resistivity in the first side wall region 42x be less than the first electrical resistivity in the inner region 41. In view of achieving both a low semi-selected leakage current and a low first fire voltage, it is preferable that the third electrical resistivity in the second side wall region 42y be less than the first electrical resistivity in the inner region 41.

Preferably, the switching layer 40 includes at least one fourth element selected from a group consisting of carbon (C), boron (B), phosphorus (P), and nitrogen (N). The switching layer 40 includes the fourth element, so as to prevent the switching layer 40 from being crystallized, and reduce the semi-selected leakage current, for example.

According to the third embodiment, the switching element having a low semi-selected leakage current and a low first fire voltage can be realized. Consequently, according to the third embodiment, the storage device that includes the switching element with excellent characteristics can be realized.

Note that the electrode structures described in the first to fourth modifications of the first embodiment are applicable to the storage device of the third embodiment.

### Fourth Embodiment

A storage device according to a fourth embodiment is different from the storage device of the first embodiment in that it is a resistive memory (ReRAM). Hereinafter, portions of the description that are redundant with the first embodiment may be omitted.

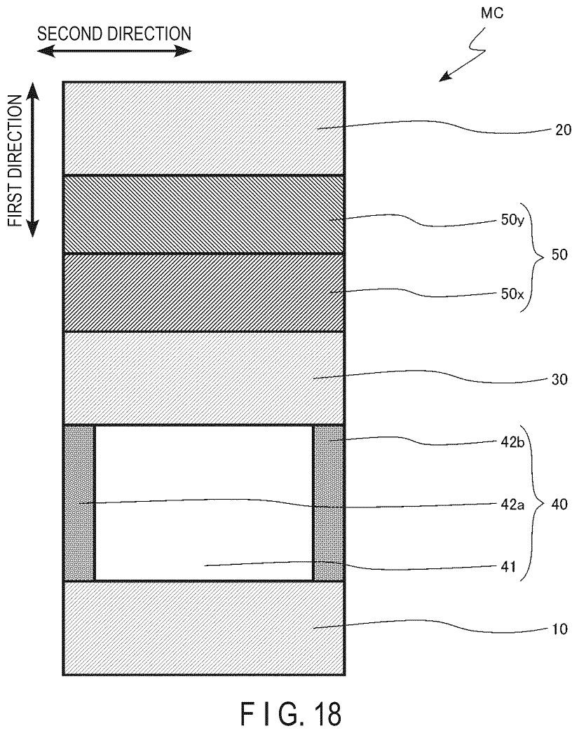

FIG. 18 is a schematic sectional view of a memory cell of the storage device of the fourth embodiment. FIG. 18 shows a section of one memory cell MC indicated by, for example, a broken-line circle in the memory cell array 100 in FIG. 1.

As shown in FIG. 18, the memory cell MC includes a lower electrode 10, an upper electrode 20, an intermediate electrode 30, a switching layer 40, and a resistive layer 50. The switching layer 40 includes an inner region 41, a first side wall region 42a, and a second side wall region 42b. The resistive layer 50 includes a high-resistance layer 50x, and a low-resistance layer 50y.

The lower electrode 10 is an example of a first conductive layer. The upper electrode 20 is an example of a second conductive layer. The intermediate electrode 30 is an example of a third conductive layer. The inner region 41 is an example of the first region. The first side wall region 42a is an example of the second region. The second side wall region 42b is an example of the third region.

The lower electrode 10, the switching layer 40, and the intermediate electrode 30 make up a switching element of the memory cell MC. The intermediate electrode 30, the resistive layer 50, and the upper electrode 20 make up a resistive element of the memory cell MC.

The configuration of the switching layer 40 is similar to that in the storage device o the first embodiment.

The resistive layer 50 includes the high-resistance layer 50x, and the low-resistance layer 50y.

The high-resistance layer 50x is made of, for example, a metal oxide. The high-resistance layer 50x is made of, for example, aluminum oxide, hafnium oxide, zirconium oxide, tantalum oxide, or niobium oxide.

The low-resistance layer 50y is made of, for example, a metal oxide. The low-resistance layer 50y is made of, for example, titanium oxide, niobium oxide, tantalum oxide, or tungsten oxide.

The resistive layer 50 has a function of storing data according to a change in resistance thereof. The resistive layer 50 has, for example, characteristics in which the electrical resistance changes with application of a predetermined voltage.

By applying a voltage to the resistive layer 50, the resistive layer 50 changes from a high-resistance state to a low-resistance state, or from the low-resistance state to the high-resistance state. By applying the voltage to the resistive layer 50, oxygen ions move between the high-resistance layer 50x and the low-resistance layer 50y, and the amount of oxygen deficiency (amount of oxygen vacancy) in the low-resistance layer 50y changes. With the amount of oxygen deficiency in the low-resistance layer 50y, the conductivity of the resistive layer 50 changes. The low-resistance layer 50y is made of what is called a vacancy modulated conductive oxide.

For example, the high-resistance state is defined as data “1”, and the low-resistance state is defined as data “0”. The memory cell MC can store one-bit data of “0” and “1”.

As described above, according to the storage device of the fourth embodiment, similar to the first embodiment, the switching element that has a low semi-selected leakage current and a low first fire voltage can be realized. Consequently, according to the fourth embodiment, the storage device that includes the switching element with excellent characteristics can be realized.

### Fifth Embodiment

A storage device according to a fifth embodiment includes a memory cell that includes a first conductive layer, a second conductive layer, and a memory layer provided between the first conductive layer and the second conductive layer. The memory layer contains: a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the at least one first element and is selected from a group consisting of aluminum (Al), zinc (Zn), tin (Sn), gallium (Ga), indium (In), and bismuth (Bi); and at least one third element selected from a group consisting of tellurium (Te), sulfur (S), selenium (Se), and antimony (Sb). The switching layer includes a first region, a second region, and a third region in a cross-section parallel to a first direction connecting the first conductive layer and the second conductive layer, and the first region is provided in the cross-section between the second region and the third region in a second direction perpendicular to the first direction. The first region includes the first oxide; the second region and the third region include the second element and the third element; the second sum of the atomic concentration of the second element and the atomic concentration of the third element in the second region is greater than the first sum of the atomic concentration of the second element and the atomic concentration of the third element in the first region; and the third sum of the atomic concentration of the second element and the atomic concentration of the third element in the third region is greater than the first sum.

The storage device of the fifth embodiment further includes a plurality of first lines, and a plurality of second lines that intersect the plurality of first lines. The memory cell is provided in a region where one of the plurality of first lines intersects one of the plurality of second lines.

The storage device of the fifth embodiment is different from the storage device of the first embodiment in that the memory cell does not include the third conductive layer and the resistive layer, and has a configuration similar to that of the switching layer in the first embodiment as the memory layer. Hereinafter, portions of the description that are redundant with the first embodiment may be omitted.

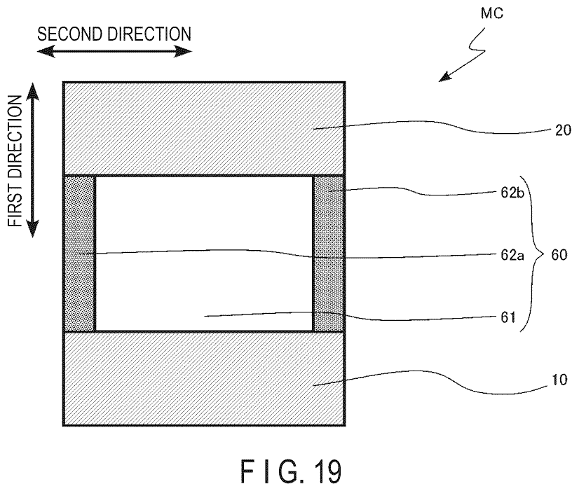

FIG. 19 is a schematic sectional view of the memory cell of the storage device of the fifth embodiment. FIG. 19 shows a section of one memory cell MC indicated by, for example, a broken-line circle in the memory cell array 100 in FIG. 1.

As shown in FIG. 19, the memory cell MC includes the lower electrode 10, the upper electrode 20, and the memory layer 60. The memory layer 60 includes an inner region 61, a first side wall region 62a, and a second side wall region 62b.

The lower electrode 10 is an example of a first conductive layer. The upper electrode 20 is an example of a second conductive layer. The inner region 61 is an example of the first region. The first side wall region 62a is an example of the second region. The second side wall region 62b is an example of the third region.

The lower electrode 10, the memory layer 60, and the upper electrode 20 make up a memory element of the memory cell MC. The memory element of the memory cell MC has a switching function, and also has a function of storing information.

The memory layer 60 has a configuration similar to that of the switching layer 40 in the first embodiment. The inner region 61, the first side wall region 62a, and the second side wall region 62b of the memory layer 60 respectively have configurations similar to those of the inner region 41, the first side wall region 42a, and the second side wall region 42b of the switching layer 40 in the first embodiment.

The memory layer 60 has nonlinear current-voltage characteristics in which the current steeply rises at a specific threshold voltage. The memory layer 60 has characteristics in which the threshold voltage changes with application of a predetermined voltage. The memory layer 60 has characteristics in which the electrical resistance changes with application of a predetermined voltage. In the fifth embodiment, the high-resistance state is a state where the resistance of the memory layer 60 at a read voltage is relatively high. In the fifth embodiment, the low-resistance state is a state where the resistance of the memory layer 60 at the read voltage is relatively low.

The memory layer 60 has a function of preventing increase in semi-selected leakage current that flows through a semi-selected cell. The memory layer 60 has a function of storing data according to a change in resistance thereof. The memory layer 60 realizes both the function of the switching layer 40 and the function of the resistive layer 50 in the first embodiment with a single layer.

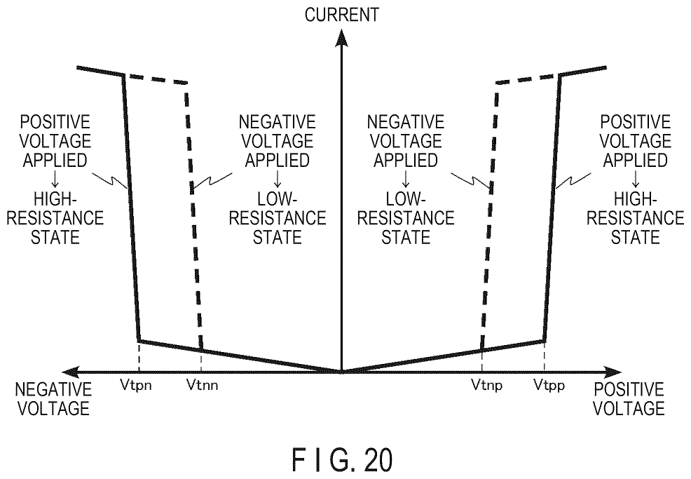

FIG. 20 is a diagram illustrating the current-voltage characteristics of the memory element in the storage device of the fifth embodiment. The horizontal axis (abscissa) indicates the voltage applied to the memory element, and the vertical axis (ordinate) indicates the current flowing through the memory element. FIG. 20 indicates, on the abscissa, the voltage applied to the upper electrode 20 with reference to the potential of the lower electrode 10. FIG. 20 shows the current-voltage characteristics of the memory layer 60 in the storage device of the fifth embodiment. FIG. 20 shows the current-voltage characteristics of the memory cell MC in the storage device of the fifth embodiment.

The memory element in the storage device of the fifth embodiment exhibits different current-voltage characteristics between a case of applying a predetermined positive voltage to the upper electrode 20 and a case of applying a predetermined negative voltage to the upper electrode 20. FIG. 20 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

A first positive voltage side threshold voltage Vtpp is higher than a second positive voltage side threshold voltage Vtnp. A first negative voltage side threshold voltage Vtpn is lower than a second negative voltage side threshold voltage Vtnn.

The memory element in the storage device of the fifth embodiment can be in each of the high-resistance state and the low-resistance state on each of the positive voltage side and the negative voltage side. In the case of applying the predetermined positive voltage to the upper electrode 20, the state is the high-resistance state on each of the positive voltage side and the negative voltage side. On the other hand, in the case of applying the predetermined negative voltage to the upper electrode 20, the state is the low-resistance state on each of the positive voltage side and the negative voltage side. Hereinafter, the high-resistance state is defined as data “1”, and the low-resistance state is defined as data “0”. The memory cell MC can store one-bit data of “0” and “1”.

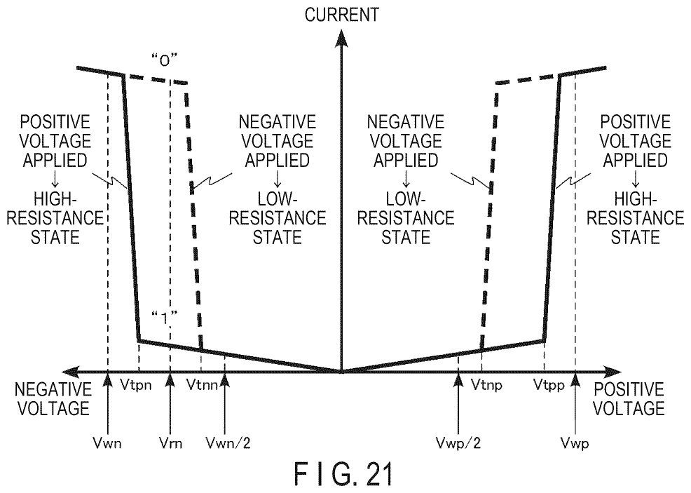

FIG. 21 is a diagram illustrating a first operation example of memory operation of the storage device of the fifth embodiment. FIG. 21 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the first operation example, the high-resistance state and the low-resistance state on the negative voltage side are used for the memory operation. In the first operation example, the negative-side read voltage Vrn is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the negative voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the negative voltage side, and data “0” is written into the selected cell.

In the first operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the first operation example, irrespective of whether the data in the selected cell is data “1” or data “0”, data destruction due to application of the negative-side read voltage Vrn does not occur. In other words, in the case of the first operation example, irrespective of whether the data in the selected cell is data “1” or data “0”, nondestructive read can be performed.

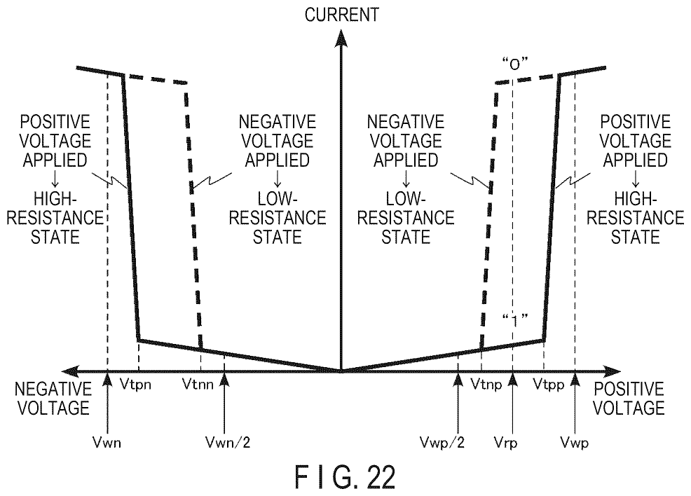

FIG. 22 is a diagram illustrating a second operation example of memory operation of the storage device of the fifth embodiment. FIG. 22 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the second operation example, the high-resistance state and the low-resistance state on the positive voltage side are used for the memory operation. In the second operation example, the positive-side read voltage Vrp is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the positive voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the positive voltage side, and data “0” is written into the selected cell.

In the second operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the second operation example, when the data in the selected cell is data “1”, data destruction due to application of the positive-side read voltage Vrp does not occur. In other words, in the case of the second operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the second operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

### (First Modification)

A storage device according to a first modification of the fifth embodiment is different from the storage device of the fifth embodiment in that the current-voltage characteristics of the memory element are different.

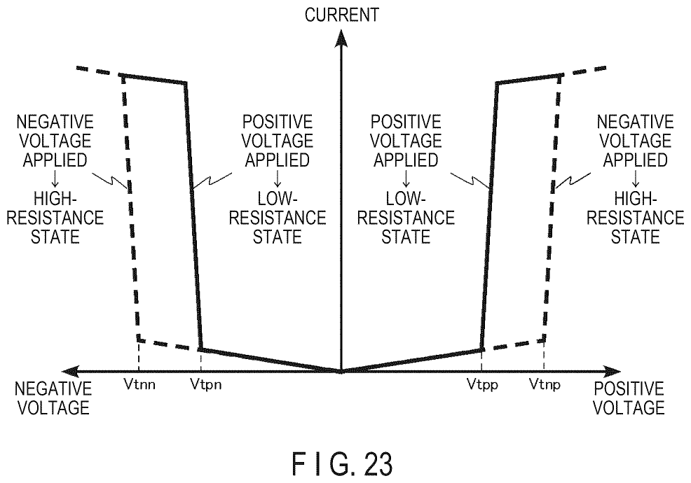

FIG. 23 is a diagram illustrating the current-voltage characteristics of the memory element in the storage device of the first modification of the fifth embodiment. The horizontal axis (abscissa) indicates the voltage applied to the memory element, and the vertical axis (ordinate) indicates the current flowing through the memory element. FIG. 23 indicates, on the abscissa, the voltage applied to the upper electrode 20 with reference to the potential of the lower electrode 10. FIG. 23 is a diagram illustrating the current-voltage characteristics of the memory layer 60 the storage device of in the first modification of the fifth embodiment. FIG. 23 shows the current-voltage characteristics of the memory cell MC in the storage device of the first modification of the fifth embodiment.

The memory element in the storage device of the first modification of the fifth embodiment exhibits different current-voltage characteristics between a case of applying a predetermined positive voltage to the upper electrode 20 and a case of applying a predetermined negative voltage to the upper electrode 20. FIG. 23 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

A first positive voltage side threshold voltage Vtpp is lower than a second positive voltage side threshold voltage Vtnp. A first negative voltage side threshold voltage Vtpn is higher than a second negative voltage side threshold voltage Vtnn.

The memory element in the storage device of the first modification of the fifth embodiment can be in each of the high-resistance state and the low-resistance state on each of the positive voltage side and the negative voltage side. In the case of applying the predetermined positive voltage to the upper electrode 20, the state is the low-resistance state on each of the positive voltage side and the negative voltage side. On the other hand, in the case of applying the predetermined negative voltage to the upper electrode 20, the state is the high-resistance state on each of the positive voltage side and the negative voltage side. Hereinafter, the high-resistance state is defined as data “1”, and the low-resistance state is defined as data “0”. The memory cell MC can store one-bit data of “0” and “1”.

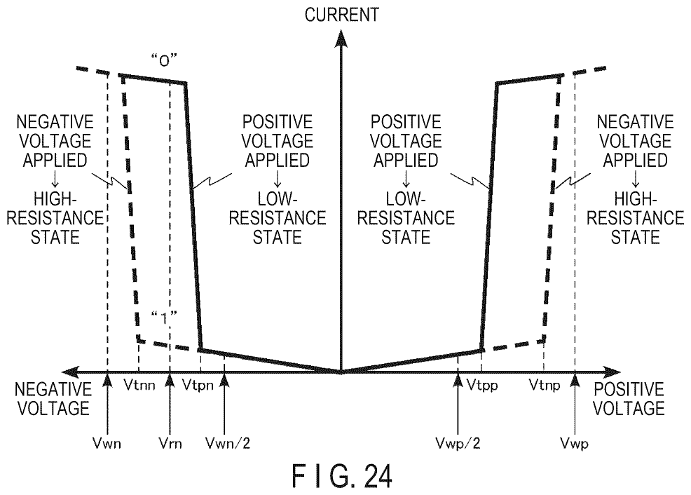

FIG. 24 is a diagram illustrating a third operation example of memory operation of the storage device of the first modification of the fifth embodiment. FIG. 24 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the third operation example, the high-resistance state and the low-resistance state on the negative voltage side are used for the memory operation. In the third operation example, the negative-side read voltage Vrn is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the negative voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the negative voltage side, and data “0” is written into the selected cell.

In the third operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the third operation example, when the data in the selected cell is data “1”, data destruction due to application of the negative-side read voltage Vrn does not occur. In other words, in the case of the third operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the third operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

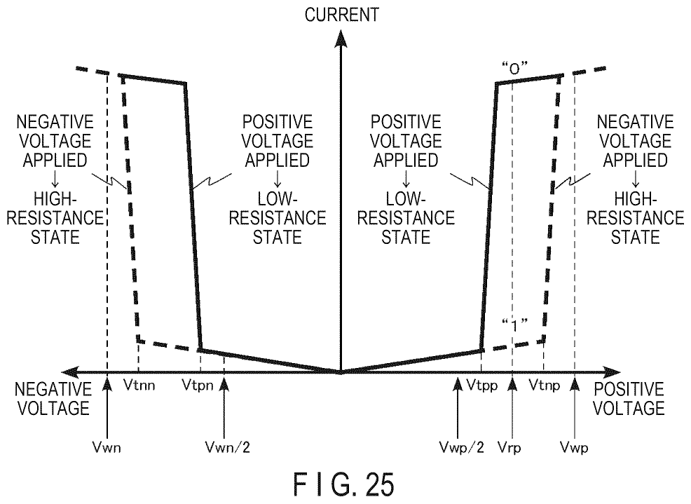

FIG. 25 is a diagram illustrating a fourth operation example of memory operation of the storage device of the first modification of the fifth embodiment. FIG. 25 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the fourth operation example, the high-resistance state and the low-resistance state on the positive voltage side are used for the memory operation. In the fourth operation example, the positive-side read voltage Vrp is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the positive voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the positive voltage side, and data “0” is written into the selected cell.

In the fourth operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the fourth operation example, irrespective of whether the data in the selected cell is data “1” or data “0”, data destruction due to application of the positive-side read voltage Vrp does not occur. In other words, in the case of the fourth operation example, irrespective of whether the data in the selected cell is data “1” or data “0”, nondestructive read can be performed.

### (Second Modification)

A storage device according to a second modification of the fifth embodiment is different from the storage device of the fifth embodiment in that the current-voltage characteristics of the memory element are different.

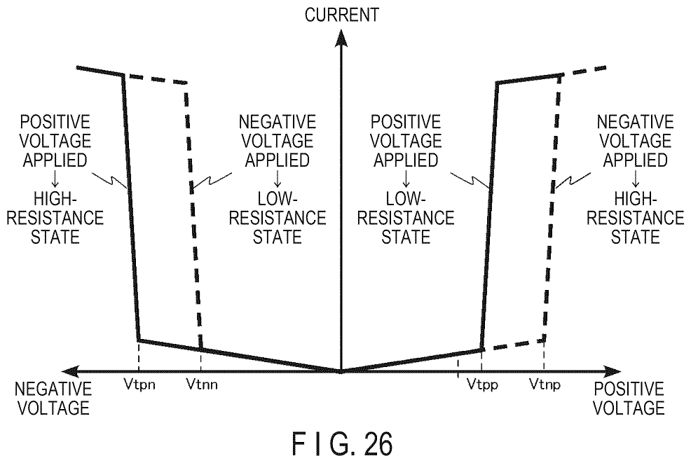

FIG. 26 is a diagram illustrating the current-voltage characteristics of the memory element in the storage device of the second modification of the fifth embodiment. The horizontal axis (abscissa) indicates the voltage applied to the memory element, and the vertical axis (ordinate) indicates the current flowing through the memory element. FIG. 26 indicates, on the abscissa, the voltage applied to the upper electrode 20 with reference to the potential of the lower electrode 10. FIG. 26 is a diagram illustrating the current-voltage characteristics of the memory layer 60 in the storage device of the second modification of the fifth embodiment. FIG. 26 is a diagram illustrating the current-voltage characteristics of the memory cell MC in the storage device of the second modification of the fifth embodiment.

The memory element in the storage device of the second modification of the fifth embodiment exhibits different current-voltage characteristics between a case of applying a predetermined positive voltage to the upper electrode 20 and a case of applying a predetermined negative voltage to the upper electrode 20. FIG. 26 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

The first positive voltage side threshold voltage Vtpp is lower than the second positive voltage side threshold voltage Vtnp. The first negative voltage side threshold voltage Vtpn is lower than the second negative voltage side threshold voltage Vtnn.

The memory element in the storage device of the second modification of the fifth embodiment can be in each of the high-resistance state and the low-resistance state on each of the positive voltage side and the negative voltage side. In the case of applying the predetermined positive voltage to the upper electrode 20, the state is the low-resistance state on the positive voltage side, and the high-resistance state on the negative voltage side. On the other hand, in the case of applying the predetermined negative voltage to the upper electrode 20, the state is the high-resistance state on the positive voltage side, and the low-resistance state on the negative voltage side. Hereinafter, the high-resistance state is defined as data “1”, and the low-resistance state is defined as data “0”. The memory cell MC can store one-bit data of “0” and “1”.

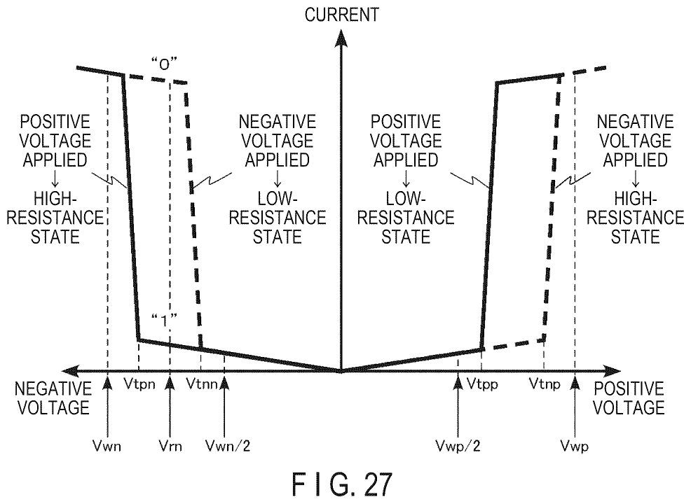

FIG. 27 is a diagram illustrating a fifth operation example of memory operation of the storage device of the second modification of the fifth embodiment. FIG. 27 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the fifth operation example, the high-resistance state and the low-resistance state on the negative voltage side are used for the memory operation. In the fifth operation example, the negative-side read voltage Vrn is used as a read voltage.

When data “1” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the high-resistance state is achieved on the negative voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the negative voltage side, and data “0” is written into the selected cell.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the fifth operation example, irrespective of whether the data in the selected cell is data “1” or data “0”, data destruction due to application of the negative-side read voltage Vrn does not occur. In other words, in the case of the fifth operation example, irrespective of whether the data in the selected cell is data “1” or data “0”, nondestructive read can be performed.

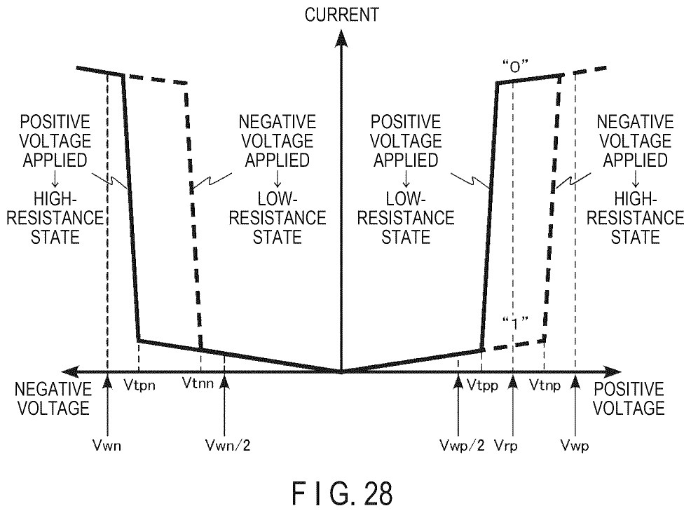

FIG. 28 is a diagram illustrating a sixth operation example of memory operation of the storage device of the second modification of the fifth embodiment. FIG. 28 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the sixth operation example, the high-resistance state and the low-resistance state on the positive voltage side are used for the memory operation. In the sixth operation example, the positive-side read voltage Vrp is used as a read voltage.

When data “1” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the high-resistance state is achieved on the positive voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the positive voltage side, and data “0” is written into the selected cell.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the sixth operation example, irrespective of whether the data in the selected cell is data “1” or data “0”, data destruction due to application of the positive-side read voltage Vrp does not occur. In other words, in the case of the sixth operation example, irrespective of whether the data in the selected cell is data “1” or data “0”, nondestructive read can be performed.

### (Third Modification)

A storage device according to a third modification of the fifth embodiment is different from the storage device of the fifth embodiment in that the current-voltage characteristics of the memory element are different.

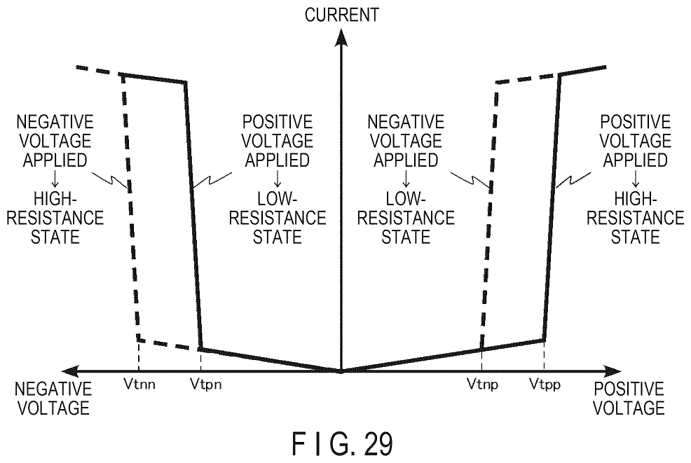

FIG. 29 is a diagram illustrating the current-voltage characteristics of the memory element in the storage device of the third modification of the fifth embodiment. The horizontal axis (abscissa) indicates the voltage applied to the memory element, and the vertical axis (ordinate) indicates the current flowing through the memory element. FIG. 29 indicates, on the abscissa, the voltage applied to the upper electrode 20 with reference to the potential of the lower electrode 10. FIG. 29 is a diagram illustrating the current-voltage characteristics of the memory layer 60 in the third modification of the fifth embodiment. FIG. 29 is a diagram illustrating the current-voltage characteristics of the memory cell MC in the third modification of the fifth embodiment.

The memory element in the storage device of the third modification of the fifth embodiment exhibits different current-voltage characteristics between a case of applying a predetermined positive voltage to the upper electrode 20 and a case of applying a predetermined negative voltage to the upper electrode 20. FIG. 29 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

The first positive voltage side threshold voltage Vtpp is higher than the second positive voltage side threshold voltage Vtnp. The first negative voltage side threshold voltage Vtpn is higher than the second negative voltage side threshold voltage Vtnn.

The memory element in the storage device of the third modification of the fifth embodiment can be in each of the high-resistance state and the low-resistance state on each of the positive voltage side and the negative voltage side. In the case of applying the predetermined positive voltage to the upper electrode 20, the state is the high-resistance state on the positive voltage side, and the low-resistance state on the negative voltage side. On the other hand, in the case of applying the predetermined negative voltage to the upper electrode 20, the state is the low-resistance state on the positive voltage side, and the high-resistance state on the negative voltage side. Hereinafter, the high-resistance state is defined as data “1”, and the low-resistance state is defined as data “0”. The memory cell MC can store one-bit data of “0” and “1”.

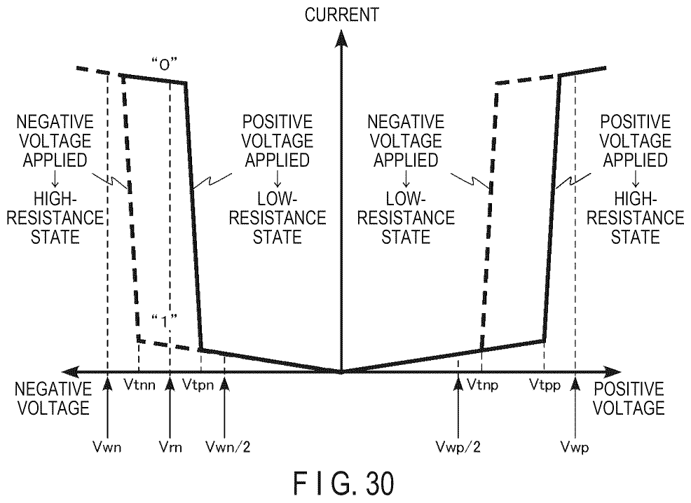

FIG. 30 is a diagram illustrating a seventh operation example of memory operation of the storage device of the third modification of the fifth embodiment. FIG. 30 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the seventh operation example, the high-resistance state and the low-resistance state on the negative voltage side are used for the memory operation. In the seventh operation example, the negative-side read voltage Vrn is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the negative voltage side, and data “1” is written into the selected cell.

When data “0” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the low-resistance state is achieved on the negative voltage side, and data “0” is written into the selected cell.

In the seventh operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be realized.

In the seventh operation example, in the case where data stored in the selected cell is data “1” when data “0” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “0” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the seventh operation example, when the data in the selected cell is data “1”, data destruction due to application of the negative-side read voltage Vrn does not occur. In other words, in the case of the seventh operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the seventh operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

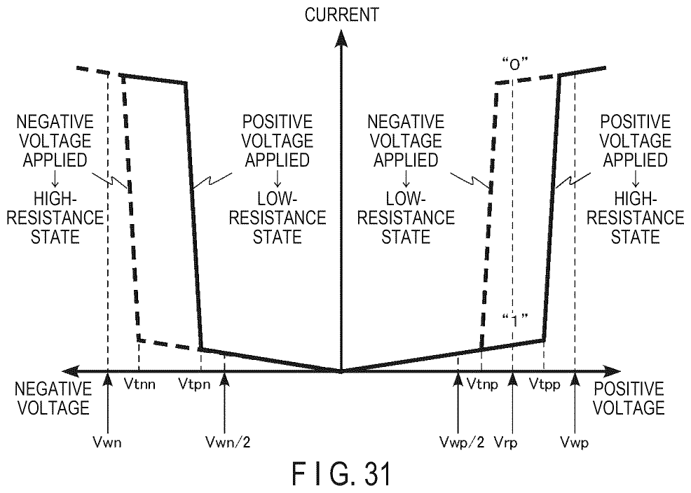

FIG. 31 is a diagram illustrating an eighth operation example of memory operation of the storage device of the third modification of the fifth embodiment. FIG. 31 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the eighth operation example, the high-resistance state and the low-resistance state on the positive voltage side are used for the memory operation. In the eighth operation example, the positive-side read voltage Vrp is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the positive voltage side, and data “1” is written into the selected cell.

When data “0” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the low-resistance state is achieved on the positive voltage side, and data “0” is written into the selected cell.

In the eighth operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be realized.

In the eighth operation example, in the case where data stored in the selected cell is data “1” when data “0” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “0” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be realized.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the eighth operation example, when the data in the selected cell is data “1”, data destruction due to application of the positive-side read voltage Vrp does not occur. In other words, in the case of the eighth operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the eighth operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

In each of the storage devices of the fifth embodiment and its modifications, the memory element of the memory cell MC has the switching function, and also has a function of storing information. The memory layer 60 realizes the function of the switching layer 40 and the function of the resistive layer 50 in the first embodiment with a single layer. The memory layer 60 in the fifth embodiment has the switching function and the memory function with a single layer, thereby allowing the structure of the memory cell MC to be a simple structure.

The memory layer 60 of each of the storage devices of the fifth embodiment and its modifications has a configuration similar to that of the switching layer 40 in the first embodiment. Consequently, according to the fifth embodiment and its modifications, similar to the first embodiment, the switching element that has a low semi-selected leakage current and a low first fire voltage can be realized. Thus, the storage device that includes the switching element with excellent characteristics can be realized.

Note that a plurality of current-voltage characteristics of the memory elements described in the fifth embodiment and its modifications can be realized by adopting the memory layer 60 that has an appropriate chemical composition, for example.

### Sixth Embodiment

A storage device according to a sixth embodiment includes a memory cell that includes a first conductive layer, a second conductive layer, and a memory layer provided between the first conductive layer and the second conductive layer. The memory layer includes: a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the at least one first element and is selected from a group consisting of aluminum (Al), zinc (Zn), tin (Sn), gallium (Ga), indium (In), and bismuth (Bi); and at least one third element selected from a group consisting of tellurium (Te), sulfur (S), selenium (Se), and antimony (Sb). The switching layer includes a first region, a second region, and a third region in a cross-section parallel to a first direction connecting the first conductive layer and the second conductive layer, and the first region is provided in the cross-section between the second region and the third region in a second direction perpendicular to the first direction. The first region includes the first oxide; the second region and the third region include the second element and the third element; a second density of chemical bonds between the third element and the third element in the second region is greater than a first density of chemical bonds between the third element and the third element in the first region; and a third density of chemical bonds between the third element and the third element in the third region is greater than the first density.

The storage device of the sixth embodiment further includes a plurality of first lines, and a plurality of second lines that intersect the plurality of first lines. The memory cell is provided in a region where one of the plurality of first lines intersects one of the plurality of second lines.

The storage device of the sixth embodiment is different from the storage device of the fifth embodiment in that a configuration similar to that of the switching layer in the third embodiment is included as the memory layer. Hereinafter, portions of the description that are redundant with the third embodiment or the fifth embodiment may be omitted.

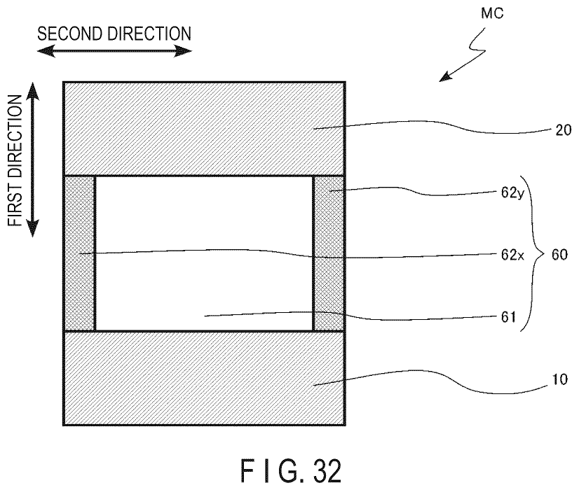

FIG. 32 is a schematic sectional view of the memory cell of the storage device in the sixth embodiment. FIG. 32 is a diagram corresponding to FIG. 19 of the fifth embodiment. FIG. 32 shows a section of one memory cell MC indicated by, for example, a broken-line circle in the memory cell array 100 in FIG. 1.

As shown in FIG. 32, the memory cell MC includes the lower electrode 10, the upper electrode 20, and the memory layer 60. The memory layer 60 includes an inner region 61, a first side wall region 62x, and a second side wall region 62y.

The lower electrode 10 is an example of a first conductive layer. The upper electrode 20 is an example of a second conductive layer. The inner region 61 is an example of the first region. The first side wall region 62x is an example of the second region. The second side wall region 62y is an example of the third region.

The lower electrode 10, the memory layer 60, and the upper electrode 20 make up a memory element of the memory cell MC. The memory element of the memory cell MC has a switching function, and also has a function of storing information.

The memory layer 60 has a configuration similar to that of the switching layer 40 in the third embodiment. The inner region 61, the first side wall region 62x, and the second side wall region 62y of the memory layer 60 respectively have configurations similar to those of the inner region 41, the first side wall region 42x, and the second side wall region 42y of the switching layer 40 in the third embodiment.

The memory layer 60 has nonlinear current-voltage characteristics in which the current steeply rises at a specific threshold voltage. The memory layer 60 has characteristics in which the threshold voltage changes with application of a predetermined voltage. The memory layer 60 has characteristics in which the electrical resistance changes with application of a predetermined voltage. In the sixth embodiment, the high-resistance state is a state where the resistance of the memory layer 60 at a read voltage is relatively high. In the sixth embodiment, the low-resistance state is a state where the resistance of the memory layer 60 at the read voltage is relatively low.

The memory layer 60 has a function of preventing increase in semi-selected leakage current that flows through a semi-selected cell. The memory layer 60 has a function of storing data according to a change in resistance thereof. The memory layer 60 realizes both the function of the switching layer 40 and the function of the resistive layer 50 in the third embodiment with a single layer.

The memory layer 60 of the storage device of the sixth embodiment has a configuration similar to that of the switching layer 40 in the third embodiment. Consequently, according to the sixth embodiment, similar to the third embodiment, the switching element that has a low semi-selected leakage current and a low first fire voltage can be realized. Thus, the storage device that includes the switching element with excellent characteristics can be realized.

Note that current-voltage characteristics similar to the multiple current-voltage characteristics of the memory element described in the fifth embodiment and its modifications can be realized in the sixth embodiment.

In the first to third embodiments, description is made using the example of the magnetoresistive memory as the two-terminal storage device, and in the fourth embodiment, description is made using the example of the resistive memory as the storage device. Alternatively, the present invention is also applicable to other two-terminal storage devices. For example, the present invention is applicable to a phase change memory (PCM), or a ferroelectric random access memory (FeRAM).

The fifth embodiment has been described using, as the example, the case of applying the switching layer 40 of the first embodiment to the memory layer 60. Alternatively, the switching layer 40 of the second embodiment may be applied to the memory layer 60.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A storage device, comprising a memory cell including:
a first conductive layer;
a second conductive layer;
a third conductive layer provided between the first conductive layer and the second conductive layer;
a switching layer provided between the first conductive layer and the third conductive layer; and
a resistive layer provided between the third conductive layer and the second conductive layer, wherein
the switching layer includes:
a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
at least one second element that is different from the at least one first element and is selected from a group consisting of aluminum (Al), zinc (Zn), tin (Sn), gallium (Ga), indium (In), and bismuth (Bi); and
at least one third element selected from a group consisting of tellurium (Te), sulfur (S), selenium (Se), and antimony (Sb),
the switching layer includes a first region, a second region, and a third region in a cross-section parallel to a first direction connecting the first conductive layer and the second conductive layer, and the first region is provided in the cross-section between the second region and the third region in a second direction perpendicular to the first direction,
the first region includes the first oxide,
the second region and the third region include the second element and the third element,
a second sum of an atomic concentration of the second element and an atomic concentration of the third element in the second region is greater than a first sum of an atomic concentration of the second element and an atomic concentration of the third element in the first region, and
a third sum of an atomic concentration of the second element and an atomic concentration of the third element in the third region is greater than the first sum.

2. The storage device of claim 1, wherein the switching layer includes a compound of the second element and the third element.

3. The storage device of claim 2, wherein the second region and the third region include the compound, and concentrations of the compound in the second region and the third region are greater than a concentration of the compound in the first region.

4. The storage device of claim 1, wherein
a second electrical resistivity in the second region is less than a first electrical resistivity in the first region, and
a third electrical resistivity in the third region is less than the first electrical resistivity.

5. The storage device of claim 1, wherein the switching layer further includes a fourth region provided between the first region and the first conductive layer, and a fourth sum of an atomic concentration of the second element and an atomic concentration of the third element in the fourth region is greater than the first sum.

6. The storage device of claim 1, wherein the switching layer further includes at least one fourth element selected from a group consisting of carbon (C), boron (B), phosphorus (P), and nitrogen (N).

7. The storage device of claim 1, wherein the resistive layer includes a magnetic tunnel junction.

8. The storage device of claim 1, wherein
the resistive layer has an electrical resistance that changes with application of a predetermined voltage thereto, and
the switching layer has nonlinear current-voltage characteristics in which current rises at a specific threshold voltage.

9. The storage device of claim 1, further comprising:
a plurality of first lines; and
a plurality of second lines that intersect the plurality of first lines when viewed in the first direction,
wherein the memory cell is provided in a region where one of the plurality of first lines intersects one of the plurality of second lines when viewed in the first direction.

10. A storage device, comprising a memory cell including:
a first conductive layer;
a second conductive layer;
a third conductive layer provided between the first conductive layer and the second conductive layer;
a switching layer provided between the first conductive layer and the third conductive layer; and
a resistive layer provided between the third conductive layer and the second conductive layer, wherein
the switching layer includes:
a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
at least one second element that is different from the at least one first element and is selected from a group consisting of aluminum (Al), zinc (Zn), tin (Sn), gallium (Ga), indium (In), and bismuth (Bi); and
at least one third element selected from a group consisting of tellurium (Te), sulfur (S), selenium (Se), and antimony (Sb),
the switching layer includes a first region, a second region, and a third region in a cross-section parallel to a first direction connecting the first conductive layer and the second conductive layer, and the first region is provided in the cross-section between the second region and the third region in a second direction perpendicular to the first direction,
the first region includes the first oxide,
the second region and the third region include the second element and the third element,
a second density of chemical bonds between the third element and the third element in the second region is greater than a first density of chemical bonds between the third element and the third element in the first region, and
a third density of chemical bonds between the third element and the third element in the third region is greater than the first density.

11. The storage device of claim 10, wherein the switching layer includes a compound of the second element and the third element.

12. The storage device of claim 11, wherein the first region includes the compound, and concentrations of the compound in the second region and the third region are less than a concentration of the compound in the first region.

13. The storage device of claim 10, wherein
the second region and the third region include a second oxide of the second element,
a second concentration of the second oxide in the second region is greater than a first concentration of the second oxide in the first region, and
a third concentration of the second oxide in the third region is greater than the first concentration.

14. The storage device of claim 10, wherein
a second electrical resistivity in the second region is less than a first electrical resistivity in the first region, and
a third electrical resistivity in the third region is less than the first electrical resistivity.

15. The storage device of claim 10, wherein the switching layer further includes at least one fourth element selected from a group consisting of carbon (C), boron (B), phosphorus (P), and nitrogen (N).

16. The storage device of claim 10, wherein the resistive layer includes a magnetic tunnel junction.

17. The storage device of claim 10, wherein
the resistive layer has an electrical resistance that changes with application of a predetermined voltage, and
the switching layer has nonlinear current-voltage characteristics in which current rises at a specific threshold voltage.

18. The storage device of claim 10, further comprising:
a plurality of first lines; and
a plurality of second lines that intersect the plurality of first lines when viewed in the first direction,
wherein the memory cell is provided in a region where one of the plurality of first lines intersects one of the plurality of second lines when viewed in the first direction.

19. A storage device, comprising a memory cell including:
a first conductive layer;
a second conductive layer; and
a memory layer provided between the first conductive layer and the second conductive layer, wherein
the memory layer includes:
a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
at least one second element that is different from the at least one first element and is selected from a group consisting of aluminum (Al), zinc (Zn), tin (Sn), gallium (Ga), indium (In), and bismuth (Bi); and
at least one third element selected from a group consisting of tellurium (Te), sulfur (S), selenium (Se), and antimony (Sb),
the memory layer includes a first region, a second region, and a third region in a cross-section parallel to a first direction connecting the first conductive layer and the second conductive layer, and the first region is provided in the cross-section between the second region and the third region in a second direction perpendicular to the first direction,
the first region includes the first oxide,
the second region and the third region include the second element and the third element,
a second sum of an atomic concentration of the second element and an atomic concentration of the third element in the second region is greater than a first sum of an atomic concentration of the second element and an atomic concentration of the third element in the first region, and
a third sum of an atomic concentration of the second element and an atomic concentration of the third element in the third region is greater than the first sum.

20. The storage device of claim 19, wherein the memory layer includes a compound of the second element and the third element.

21. The storage device of claim 20, wherein the second region and the third region include the compound, and concentrations of the compound in the second region and the third region are greater than a concentration of the compound in the first region.

22. The storage device of claim 19, wherein
a second electrical resistivity in the second region is less than a first electrical resistivity in the first region, and
a third electrical resistivity in the third region is less than the first electrical resistivity.

23. The storage device of claim 19, wherein the memory layer further includes a fourth region provided between the first region and the first conductive layer, and a fourth sum of an atomic concentration of the second element and an atomic concentration of the third element in the fourth region is greater than the first sum.

24. The storage device of claim 19, wherein the memory layer further includes at least one fourth element selected from a group consisting of carbon (C), boron (B), phosphorus (P), and nitrogen (N).

25. The storage device of claim 19, wherein the memory layer has nonlinear current-voltage characteristics in which current rises at a specific threshold voltage, and the threshold voltage changes with application of a predetermined voltage.

26. The storage device of claim 19, further comprising:
a plurality of first lines; and
a plurality of second lines that intersect the plurality of first lines when viewed in the first direction,
wherein the memory cell is provided in a region where one of the plurality of first lines intersects one of the plurality of second lines when viewed in the first direction.

27. A storage device, comprising a memory cell including:
a first conductive layer;
a second conductive layer; and
a memory layer provided between the first conductive layer and the second conductive layer, wherein
the memory layer includes:
a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
at least one second element that is different from the at least one first element and is selected from a group consisting of aluminum (Al), zinc (Zn), tin (Sn), gallium (Ga), indium (In), and bismuth (Bi); and
at least one third element selected from a group consisting of tellurium (Te), sulfur (S), selenium (Se), and antimony (Sb),
the memory layer includes a first region, a second region, and a third region in a cross-section parallel to a first direction connecting the first conductive layer and the second conductive layer, and the first region is provided in the cross-section between the second region and the third region in a second direction perpendicular to the first direction,
the first region includes the first oxide,
the second region and the third region include the second element and the third element,
a second density of chemical bonds between the third element and the third element in the second region is greater than a first density of chemical bonds between the third element and the third element in the first region, and
a third density of chemical bonds between the third element and the third element in the third region is greater than the first density.

28. The storage device of claim 27, wherein the memory layer includes a compound of the second element and the third element.

29. The storage device of claim 28, wherein the first region includes the compound, and concentrations of the compound in the second region and the third region are less than a concentration of the compound in the first region.

30. The storage device of claim 27, wherein
the second region and the third region include a second oxide of the second element,
a second concentration of the second oxide in the second region is greater than a first concentration of the second oxide in the first region, and
a third concentration of the second oxide in the third region is greater than the first concentration.

31. The storage device of claim 27, wherein
a second electrical resistivity in the second region is less than a first electrical resistivity in the first region, and
a third electrical resistivity in the third region is less than the first electrical resistivity.

32. The storage device of claim 27, wherein the memory layer further includes at least one fourth element selected from a group consisting of carbon (C), boron (B), phosphorus (P), and nitrogen (N).

33. The storage device of claim 27, wherein the memory layer has nonlinear current-voltage characteristics in which current rises at a specific threshold voltage, and the threshold voltage changes with application of a predetermined voltage.

34. The storage device of claim 27, further comprising:
a plurality of first lines; and
a plurality of second lines that intersect the plurality of first lines when viewed in the first direction,
wherein the memory cell is provided in a region where one of the plurality of first lines intersects one of the plurality of second lines when viewed in the first direction.
